(19) United States
(12) Patent Application Publication
(10) Pub. No.: US 2019/0348608 A1
(43) Pub. Date: Nov. 14, 2019

(54) NOVEL WEAK DONOR-ACCEPTOR CONJUGATED COPOLYMERS FOR FIELD- EFFECT TRANSISTOR APPLICATIONS

(71) Applicant: The Regents of the University of California, Oakland, CA (US)

(72) Inventors: Guillermo C. Bazan, Santa Barbara, CA (US); Ming Wang, Goleta, CA (US)

(73) Assignee: The Regents of the University of California, Oakland, CA (US)

(21) Appl. No.: 16/519,924

(22) Filed: Jul. 23, 2019

Related U.S. Application Data
(63) Continuation of application No. 15/496,826, filed on Apr. 25, 2017.
(60) Provisional application No. 62/489,303, filed on Apr. 24, 2017.
(60) Provisional application No. 62/327,311, filed on Apr. 25, 2016.

(51) Int. Cl. H01L 51/00; C08G 61/12

(52) U.S. Cl. CPC H01L 51/0036; H01L 51/0043; C08G 61/126; C08G 2261/1412; C08G 2261/18; H01L 51/0558; C08G 2261/312; C08G 2261/3243; C08G 2261/411; C08G 2261/92; H01L 51/0003; C08G 2261/122

(57) ABSTRACT

Conjugated donor-acceptor copolymers comprising a donor and an acceptor, wherein the acceptor comprises a fluorophenylene. Organic Field Effect Transistors (OFETs) comprising the conjugated donor-acceptor copolymers are also disclosed.

### CROSS REFERENCE TO RELATED APPLICATIONS

This application is a continuation under 35 U.S.C Section 120 of copending and commonly assigned U.S. Utility application Ser. No. 15/496,826, filed on Apr. 25, 2017, by Guillermo Bazan and Ming Wang, entitled “NOVEL WEAK DONOR-ACCEPTOR CONJUGATED COPOLYMERS FOR FIELD-EFFECT TRANSISTOR APPLICATIONS,” attorneys' docket no. 30794.0616USU1 (2016-609-3), which application claims the benefit under 35 U.S.C. Section 119(e) of the following co-pending and commonly-assigned U.S. Provisional patent applications:

U.S. Provisional Patent Application No. 62/327,311, filed Apr. 25, 2016, by Guillermo C. Bazan and Ming Wang, entitled “NOVEL WEAK DONOR-ACCEPTOR CONJUGATED COPOLYMERS FOR FIELD-EFFECT TRANSISTOR APPLICATIONS,” Attorney's Docket No. 30794.616-US-P1 (2016-609); and

U.S. Provisional Patent Application No. 62/489,303, filed Apr. 24, 2017, by Guillermo C. Bazan and Ming Wang, entitled “LINEAR CONJUGATED POLYMER BACKBONES IMPROVE THE ANISOTROPIC MORPHOLOGY IN NANOGROOVE ASSISTED ALIGNMENT ORGANIC FIELD-EFFECT TRANSISTOR APPLICATIONS,” Attorney's Docket No. 30794.616-US-P2 (2016-609); and

all of which applications are incorporated by reference herein.

This application is related to the following co-pending and commonly-assigned U.S. patent applications:

U.S. Provisional Patent Application No. 62/338,866, filed May 19, 2016, by Michael J. Ford, Hengbin Wang, and Guillermo Bazan, entitled “ORGANIC SEMICONDUCTOR SOLUTION BLENDS FOR SWITCHING AMBIPOLAR TRANSPORT TO N-TYPE TRANSPORT,” Attorney's Docket No., 30794.619-US-P1 (UC Ref. 2016-607-1);

U.S. Utility patent application Ser. No. 15/349,920, filed Nov. 11, 2016, by Ming Wang and Guillermo Bazan, entitled “FLUORINE SUBSTITUTION INFLUENCE ON BENZO[2,1,3]THIODIAZOLE BASED POLYMERS FOR FIELD-EFFECT TRANSISTOR APPLICATIONS,” Attorney's Docket No., 30794.607-US-P1 (2016-316), which application claims the benefit under 35 U.S.C. Section 119(e) of U.S. Provisional Patent Application No. 62/253,975, filed Nov. 11, 2015, by Ming Wang and Guillermo Bazan, entitled “FLUORINE SUBSTITUTION INFLUENCE ON BENZO[2,1,3]THIODIAZOLE BASED POLYMERS FOR FIELD-EFFECT TRANSISTOR APPLICATIONS,” Attorney's Docket No., 30794.607-US-P1 (2016-316);

U.S. Utility patent application Ser. No. 15/349,920, filed Nov. 11, 2016, by Byoung Hoon Lee, Ben B. Y. Hsu, Chan Luo, Ming Wang, Guillermo Bazan, and Alan J. Heeger, entitled “SEMICONDUCTING POLYMERS WITH MOBILITY APPROACHING ONE HUNDRED SQUARE CENTIMETERS PER VOLT PER SECOND,” Attorney's Docket No. 30794.598-US-U1 (U.C. Ref. 2016-239-1), which application claims the benefit under 35 U.S.C. Section 119(e) of U.S. Provisional Patent Application No. 62/263,058, filed Dec. 4, 2015, by Byoung Hoon Lee, Ben B. Y. Hsu, Chan Luo, Ming Wang, Guillermo Bazan, and Alan J. Heeger, entitled “SEMICONDUCTING POLYMERS WITH MOBILITY APPROACHING ONE HUNDRED SQUARE CENTIMETERS PER VOLT PER SECOND,” Attorney's Docket No. 30794.598-US-P1 (U.C. Ref. 2016-239-1);

U.S. Utility patent application Ser. No. 15/256,160, filed Sep. 2, 2016, by Byoung Hoon Lee and Alan J. Heeger, entitled “DOPING-INDUCED CARRIER DENSITY MODULATION IN POLYMER FIELD-EFFECT TRANSISTORS,” Attorney's Docket No. 30794.595-US-P1 (U.C. Ref. 2016-115), which application claims the benefit under 35 U.S.C. Section 119(e) of co-pending and commonly-assigned U.S. Provisional Patent Application No. 62/214,076, filed Sep. 3, 2015, by Byoung Hoon Lee and Alan J. Heeger, entitled “DOPING-INDUCED CARRIER DENSITY MODULATION IN POLYMER FIELD-EFFECT TRANSISTORS,” Attorney's Docket No. 30794.595-US-P1 (U.C. Ref. 2016-115-1);

U.S. Utility patent application Ser. No. 15/241,949 filed Aug. 19, 2016, by Michael Ford and Guillermo Bazan, entitled “HIGH MOBILITY POLYMER ORGANIC FIELD-EFFECT TRANSISTORS BY BLADE-COATING SEMICONDUCTOR: INSULATOR BLEND SOLUTIONS,” Attorney's Docket No. 30794.592-US-U1 (U.C. Ref. 2016-112), which application claims the benefit under 35 U.S.C. Section 119(e) of U.S. Provisional Patent Application No. 62/207,707, filed Aug. 20, 2015, by Michael Ford and Guillermo Bazan, entitled “HIGH MOBILITY POLYMER ORGANIC FIELD-EFFECT TRANSISTORS BY BLADE-COATING SEMICONDUCTOR: INSULATOR BLEND SOLUTIONS,” Attorney's Docket No. 30794.592-US-P1 (U.C. Ref. 2016-112-1); and U.S. Provisional Patent Application No. 62/262,025, filed Dec. 2, 2015, by Michael Ford and Guillermo Bazan, entitled “HIGH MOBILITY POLYMER ORGANIC FIELD-EFFECT TRANSISTORS BY BLADE-COATING SEMICONDUCTOR: INSULATOR BLEND SOLUTIONS,” Attorney's Docket No. 30794.592-US-P2 (U.C. Ref. 2016-112-2);

U.S. Utility application Ser. No. 15/213,029 filed on Jul. 18, 2016 by Byoung Hoon Lee and Alan J. Heeger, entitled “FLEXIBLE ORGANIC TRANSISTORS WITH CONTROLLED NANOMORPHOLOGY”, Attorney's Docket No. 30794.0589-US-U1 (UC Ref. 2015-977-1), which application claims the benefit under 35 U.S.C. Section 119(e) of U.S. Utility U.S. Provisional Application Ser. No. 62/193,909 filed on Jul. 17, 2015 by Byoung Hoon Lee and Alan J. Heeger, entitled “FLEXIBLE ORGANIC TRANSISTORS WITH CONTROLLED NANOMORPHOLOGY”, Attorney's Docket No. 30794.0589-US-P1 (UC Ref. 2015-977-1);

U.S. Utility patent application Ser. No. 15/058,994, filed Mar. 2, 2016, by Shrayesh N. Patel, Edward J. Kramer, Michael L. Chabinyc, Chan Luo and Alan J. Heeger, entitled “BLADE COATING ON NANOGROOVED SUBSTRATES YIELDING ALIGNED THIN FILMS OF HIGH MOBILITY SEMICONDUCTING POLYMERS,” Attorney's Docket No. 30794.583-US-P1 (U.C. Ref 2015-437), which application claims the benefit under 35 U.S.C. Section 119(e) of U.S. Provisional Patent Application No. 62/127,116, filed Mar. 2, 2015, by Shrayesh N. Patel, Edward J. Kramer, Michael L. Chabinyc, Chan Luo and Alan J. Heeger, entitled “BLADE COATING ON NANOGROOVED SUBSTRATES YIELDING ALIGNED THIN FILMS OF HIGH MOBILITY SEMICONDUCTING POLYMERS,” Attorney's Docket No. 30794.583-US-P1 (U.C. Ref 2015-437);

U.S. Utility patent application Ser. No. 14/585,653, filed on Dec. 30, 2014, by Chan Luo and Alan Heeger, entitled “HIGH MOBILITY POLYMER THIN FILM TRANSISTORS WITH CAPILLARITY MEDIATED SELF-ASSEMBLY”, Attorney's Docket No. 30794.537-US-U1 (UC Ref 2014-337), which application claims the benefit under 35 U.S.C. Section 119(e) of co-pending U.S. Provisional Patent Application Ser. No. 61/923,452, filed on Jan. 3, 2014, entitled “HIGH MOBILITY POLYMER THIN FILM TRANSISTORS WITH CAPILLARITY MEDIATED SELF-ASSEMBLY,” Attorney's Docket No. 30794.537-US-P1 (UC Ref 2014-337);

U.S. Utility patent application Ser. No. 14/426,467, filed on Mar. 6, 2015, by Hsing-Rong Tseng, Lei Ying, Ben B. Y. Hsu, Christopher J. Takacs, and Guillermo C. Bazan, entitled “FIELD-EFFECT TRANSISTORS BASED ON MACROSCOPICALLY ORIENTED POLYMERS,” which application claims the benefit under 35 U.S.C. § 365 of PCT International patent application serial no. PCT/US13/058546 filed Sep. 6, 2013, which application claims the benefit under 35 U.S.C. Section 119(e) of co-pending U.S. Provisional Patent Application Serial Nos. 61/698,065, filed on Sep. 7, 2012, and 61/863,255, filed on Aug. 7, 2013, entitled “FIELD-EFFECT TRANSISTORS BASED ON MACROSCOPICALLY ORIENTED POLYMERS,” (UC REF 2013-030); and

U.S. Utility patent application Ser. No. 13/526,371, filed on Jun. 18, 2012, by G. Bazan, L. Ying, B. Hsu, W. Wen, H-R Tseng, and G. Welch entitled “REGIOREGULAR PYRIDAL[2,1,3]THIADIAZOLE PI-CONJUGATED COPOLYMERS FOR ORGANIC SEMICONDUCTORS” (Attorney Docket No. 1279-543 and U.C. Docket No. 2011-577-3), which application claims priority under 35 U.S.C. § 119(e) to U.S. Provisional Patent Application Ser. No. 61/498,390, filed on Jun. 17, 2011, by G. Bazan, L. Ying, B. Hsu, and G. Welch entitled “REGIOREGULAR CONSTRUCTIONS FOR THE SYNTHESIS OF THIADIAZOLO (3,4) PYRIDINE CONTAINING NARROW BAND GAP CONJUGATED POLYMERS” (Attorney Docket No. 1279-543P and U.C. Docket No. 2011-577-1) and U.S. Provisional Patent Application Ser. No. 61/645,970, filed on May 11, 2012, by G. Bazan, L. Ying, and Wen, entitled “REGIOREGULAR PYRIDAL[2,1,3]THIADIAZOLE PI-CONJUGATED COPOLYMERS FOR ORGANIC SEMICONDUCTORS” (Attorney Docket No. 1279-543P2 and U.C. Docket No. 2011-577-2);

all of which applications are incorporated by reference herein.

### BACKGROUND OF THE INVENTION

### 1. Field of the Invention

The present invention is related to semiconducting polymers useful in organic devices.

### 2. Description of the Related Art

(Note: This application references a number of different references as indicated throughout the specification by one or more reference numbers in superscripts, e.g., ^{x}. A list of these different references ordered according to these reference numbers can be found below in the section entitled “References.” Each of these references is incorporated by reference herein.)

Narrow bandgap (E_{g}) conjugated polymers are under intense investigation for organic field-effect transistor (OFET) applications. In recent years, the highest performing polymer OFETs have been based on such types of polymers¹: for example, diketopyrrolopyrrole (DPP) based polymers,² isoindigo (IDG) based polymers³, benzo[2,1,3]thiadiazole (BT) based polymers, and their deriatives.⁴ These polymer structures typically utilize an alternating donor-acceptor design strategy, where an electron rich moiety is the donor (D) and an electron deficient moiety is the acceptor (A) in each repeat unit.⁵ However, in the reported D-A type high mobility polymers, strong acceptors (DPP, IDG, BT, and their derivatives) usually induce an ambipolar charge transporting effect, which can prevent turning off the device in saturation and sometimes causes interfacial traps in p-type OFETs.⁶ These undesirable features have been attributed to electron injection from the electrode in the device, which can be related to the intrinsic low-lying polymer lowest unoccupied molecular orbital (LUMO) energy level.⁷ What is needed then, are OFET device structures having improved performance. Embodiments of the present invention satisfy this need.

### SUMMARY OF THE INVENTION

The present disclosure reports on novel conjugated donor-acceptor copolymers that may be incorporated into organic devices. Embodiments of the donor-acceptor copolymers comprise at least one donor and at least one fluorophenylene unit as an acceptor, the at least one fluorophenylene unit selected from:

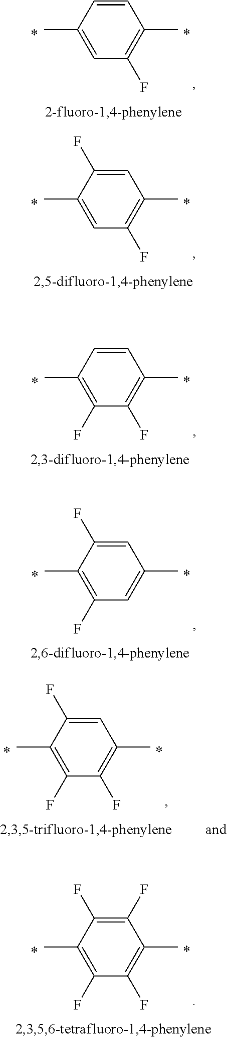

To better illustrate the donor-acceptor copolymers and methods disclosed herein, a non-limiting list of examples is provided here:

In Example 1, the donor comprises a dithiophene of the structure:

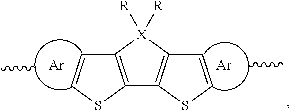

wherein each Ar is independently a substituted or non-substituted aromatic functional group, or each Ar is independently nothing and the valence of its respective thiophene ring is completed with hydrogen, each R is independently hydrogen or a substituted or non-substituted alkyl, aryl, or alkoxy chain, and X is C, Si, Ge, N or P.

In Example 2, the copolymer has a bandgap of at least 1.9 eV (e.g., 1.9-2.1 eV) and/or a LUMO having an energy greater than −3.5 electron volts.

In Example 3, the donor-acceptor copolymers are regioregular and comprise any donor, and 2-fluoro-1,4-phenylene, 2,6-difluoro-1,4-phenylene, or 2,3,5-trifluoro-1,4-phenylene as the acceptor.

In Example 4, the donor-acceptor copolymers of one or any of combination of Examples 1-3 are stacked in a crystalline structure characterized by one or more peaks having a full width at half maximum of less than 0.1 Angstroms⁻¹ as measured by an out of plane grazing incidence wide angle X-ray Scattering (GIWAXS) measurement of the crystalline structure.

In Example 5, the subject matter of one or any combination of Examples 1-4 comprises a film on a substrate, the film comprising the donor-acceptor copolymers, and the film having a surface roughness of less than 2 nanometers over a 5 micron by 5 micron area.

In Example 6, the copolymers of one or any combination of Examples 1-5 are non-aligned polymers, e.g., fabricated on a smooth substrate.

In Example 7, the copolymers of one or any combination of Examples 1-5 are aligned polymers, e.g., fabricated either on a grooved (e.g., nanogrooved) substrate.

In Example 8, the copolymers described in one or any combination of Examples 1-7 are disposed in high mobility Organic Thin Film Transistor (OTFT) devices.

In Example 9, the aligned donor-acceptor copolymer in the OTFT device of Example 8 comprises any donor and the acceptor comprises at least one fluorophenylene selected from 2-fluoro-1,4-phenylene, 2,3-difluoro-1,4-phenylene, 2,6-difluoro-1,4-phenylene, 2,3,5-trifluoro-1,4-phenylene, and 2,3,5,6-tetrafluoro-1,4-phenylene.

In Example 10, the aligned donor acceptor copolymer in the OTFT device of Example 8 comprises a cyclopentadithiophene (CDT) type donor and the acceptor comprising at least one fluorophenylene selected from 2-fluoro-1,4-phenylene, 2,3-difluoro-1,4-phenylene, 2,5-difluoro-1,4-phenylene, 2,6-difluoro-1,4-phenylene, 2,3,5-trifluoro-1,4-phenylene, and 2,3,5,6-tetrafluoro-1,4-phenylene.

In Example 11, the subject matter of one or any combination of Examples 8-10 includes the donor-acceptor copolymers cast from a solution such that the OFET has the mobility in a saturation regime of at least 0.68 cm²V⁻¹s⁻¹ (or at least 2 cm²V⁻¹s⁻¹) and/or an on/off ratio of at least 10⁴ (or at least 10⁵).

In Example 12, the subject matter of one or any combination of Examples 8-11 includes the OFETs exhibiting unipolar p-type transport characteristics.

In Example 13, the copolymer of one or any combination of Examples 1-12 is fabricated using a process comprising reacting one or more first monomers, each comprising the donor (e.g., a dithiophene) and an organostannane, with one or more second monomers each comprising benzene substituted with iodine, bromine, and fluorine, under conditions to form one or more intermediary compounds. The process then comprises reacting the first monomers with the intermediary compounds to form the donor-acceptor copolymer.

In Example 14, the copolymer of one or any combination of Examples 1-12 is fabricated using a process comprising reacting one or more first monomers, each comprising a donor (e.g., dithiophene) and an organostannane, with one or more fluorinated and brominated monomers, under conditions to form the donor-acceptor copolymers.

In Example 15, the subject matter of one or any combination of Examples 8-14 further comprises heating the regioregular donor-acceptor copolymers so as to maintain or increase a mobility of the regioregular donor-acceptor copolymers.

### BRIEF DESCRIPTION OF THE DRAWINGS

Referring now to the drawings in which like reference numbers represent corresponding parts throughout:

FIG. 1 is an illustration of the polymer design strategy, illustrating weak donor-acceptor copolymers according to one or more embodiments of the present invention as compared to strong donor-acceptor copolymers.

FIG. 2(a) shows ultraviolet-visible (UV-vis) absorption of polymers in solution and FIG. 2(b) shows ultraviolet-visible (UV-vis) absorption of polymers in a thin film, wherein the polymers were fabricated according to Scheme 1.

FIGS. 3(a)-3(c) illustrate simplified oligomers and the side-view of B3LYP/6-311G(d,p)-optimized structures for PhF0 (FIG. 3(a)), PhF1 (FIG. 3(b)), and PhF2,5 (FIG. 3(c)) according to one or more embodiments of the invention.

FIGS. 4(a), 4(c) and 4(e) show output curves and FIGS. 4(b), 4(d), and 4(f) show transfer curves, for OFET devices comprising PhF0 (r.t.) (FIGS. 4(a) and 4(b)), PhF1 (annealed at 200° C.) (FIGS. 4(c) and 4(d)), and PhF2,5 (annealed at 200° C.) (FIGS. 4(e) and 4(f)), for OFET devices comprising the donor-acceptor copolymers fabricated according Scheme 1.

FIGS. 5(a)-5(f) illustrates atomic force microscopy (AFM) topographic images (scale: 5 μm×5 μm) at r.t. for films fabricated according to Scheme 1 comprising PhF0 (FIG. 5(a)), PhF1 (FIG. 5(b)), and PhF2,5 (FIG. 5(c)) and for films annealed at 200° C. and comprising PhF0 (FIG. 5(d)), PhF1 (FIG. 5(e)), PhF2,5 (FIG. 5(f)).

FIGS. 6(a)-6(b) shows line-cut profiles of PhF2,5 fabricated according to Scheme 1 and obtained using GIWAXS measurements.

FIGS. 7(a)-7(c) show single crystals structures according to embodiments of the present invention and proposed impact on the polymer backbone shape, for PhF2,3 (FIG. 7(a)); PhF2,5 (FIG. 7(b)); PhF2,6 (FIG. 7(a)). (where F atom in PhF2,3 and PhF2,5 single crystals is labelled 700; for PhF2,6, F and H on phenylene are not distinguishable because there is no preferential of F or H orientations in the single crystal).

FIG. 8(a) shows UV-vis in solution, FIG. 8(b) shows UV-vis in solution at 70° C.; FIG. 8(c) UV-vis in thin films; and FIG. 8(d) DSC measurements, for structures according to embodiments of the present invention.

FIGS. 9(a), 9(c), and 9(e) show output curves for PhF2,3, PhF2,5, and PhF2,6 OFET devices respectively, and FIGS. 9(b), 9(d), and 9(f) show transfer curves of the PhF2,3, PhF2,5, and PhF2,6 OFET devices, wherein the devices use normal substrates.

FIGS. 10(a), 10(c), and 10(e) show transfer curves of OFET devices according to one or more embodiments of the present invention using nanogroove (NG) substrates and FIGS. 10(b), 10(d), and 10(f) show their μ distributions.

FIGS. 11(a)-11(i) shows 2D GIWAXs images of films according to one or more embodiments of the present invention, plotting q_{xy} (Angstrom⁻¹) on the x axis and q_{z} (Angstrom⁻¹) on the y axis, for PhF2,3 (FIG. 11(a) w/o NQ FIG. 11(b) parallel, and FIG. 11(c) Perpendicular); for PhF2,6 (FIG. 11(d) w/o NQ FIG. 11(e) Parallel, and FIG. 11(f) Perpendicular; for PhF2,5 (FIG. 11(g) w/o NG, FIG. 11(h) Parallel, and FIG. 11(i) Perpendicular), and FIG. 11(j) shows the GIWAXS set-up.

FIGS. 12(a)-12(f) show GIWAXS line-cut profiles for the films according to one or more embodiments of the invention, intensity (arbitrary units) as a function of q_{z} (Angstrom-) for out-of-plane: PhF2,3 (FIG. 12(a)), PhF2,6 (FIG. 12(c)) PhF2,5 (FIG. 12(e); and intensity (arbitrary units) as a function of q_{xy} (Angstrom-) for in-plane: PhF2,3 (FIG. 12(b), PhF2,6 (FIG. 12(d)), and PhF2,5 (FIG. 12(f).

FIG. 13a is a flowchart illustrating a method of fabricating a device according to one or more embodiments of the present invention.

FIG. 13b is a flowchart illustrating a method of fabricating donor-acceptor copolymers according to one or more embodiments of the present invention.

FIG. 14 illustrates an OFET comprising the copolymers according to one or more embodiments of the present invention.

### DETAILED DESCRIPTION OF THE INVENTION

In the following description of the preferred embodiment, reference is made to a specific embodiment in which the invention may be practiced. It is to be understood that other embodiments may be utilized and structural changes may be made without departing from the scope of the present invention.

Technical Description

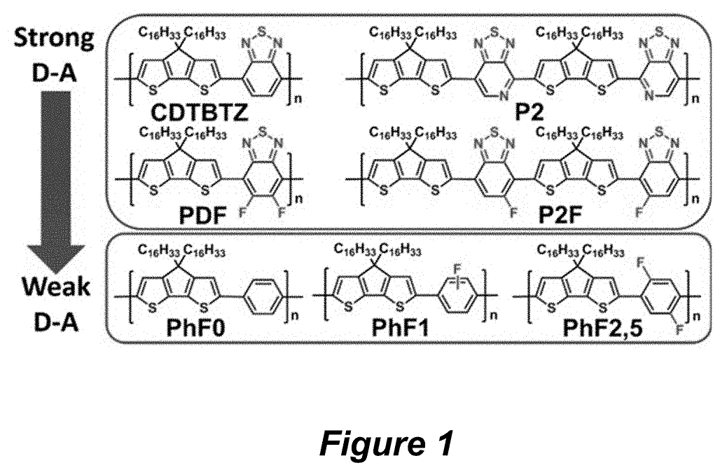

As shown in the FIG. 1, Miillen et al. developed a high mobility D-A type polymer CDTBTZ,⁹ which contains 4,4-dihexadecyl-4H-cyclopenta[1,2-b:5,4-b′]dithiophene (CDT) as the donor unit and benzo[2,1,3]thiadiazole (BT) as the acceptor unit. In another work¹⁰, the BT group was modified to pyridal[2,1,3]thiadiazole (PT) and fluorinated BTs, achieving high mobility as well. Nevertheless, the above BT, PT and fluorinated BTs are relatively strong electron acceptors¹¹ that result in low-lying LUMO levels (lower than −3.5 eV) together with narrow bandgaps. Consequently, the OFETs based on these polymers suffer from an electron injection issue.⁶ The inventors of the present invention, on the other hand, expect designing polymers with high-lying LUMO levels can suppress such electron injection defects and obtain improved p-only charge transporting behavior. For example, several polymers using all donor moieties in the backbone were reported with pure p-type charge transporting characteristics, such as PBTTT and its derivatives.⁸ Nevertheless, developing new high-lying LUMO materials having high mobility, relative to those reported D-A type polymers, still remains a challenge. Embodiments of the present invention satisfy this need.

In one illustrative design strategy, the inventors considered new polymer designs that (1) achieve the high-lying LUMO levels necessary to eliminate the electron injection and (2) form well-ordered thin films essential for improved charge transport. To this end, electron deficient groups were first eliminated, but the polymer backbone basis from the above strong D-A polymers was preserved. In one example, a donor-donor type copolymer (PhF0) is obtained with CDT and a phenylene in the repeat unit. Second, fluorine atoms were introduced on the phenyl, as fluorine is considered a weak electron-withdrawing group relative to the thiadiazole building block in the strong D-A polymers described above. Fluorine atoms could further influence both intra-chain and inter-chain interactions due to the non-bonding interactions with adjacent hydrogen and sulfur atoms.^{8d,12}

### 1. First Synthesis Example (Scheme 1)

Both the mono-fluorine substituted polymer PhF1 and the di-fluorine substituted polymer PhF2,5 were synthesized to study the fluorine quantity influence on the material properties and device performance. The inventors expected the resulting donor-acceptor copolymers to possess high-lying LUMOs (due to the weak electron-withdrawing ability of fluorinated phenylene) as well as exhibit desirable self-assembling capability (due to the polymer backbone, alkyl chains, and F . . . H, F . . . S non-bonding interactions, which should be similar to the N . . . H and N . . . S interactions in the above mentioned CDTBTZ, P2 polymers^{12a,12d}).

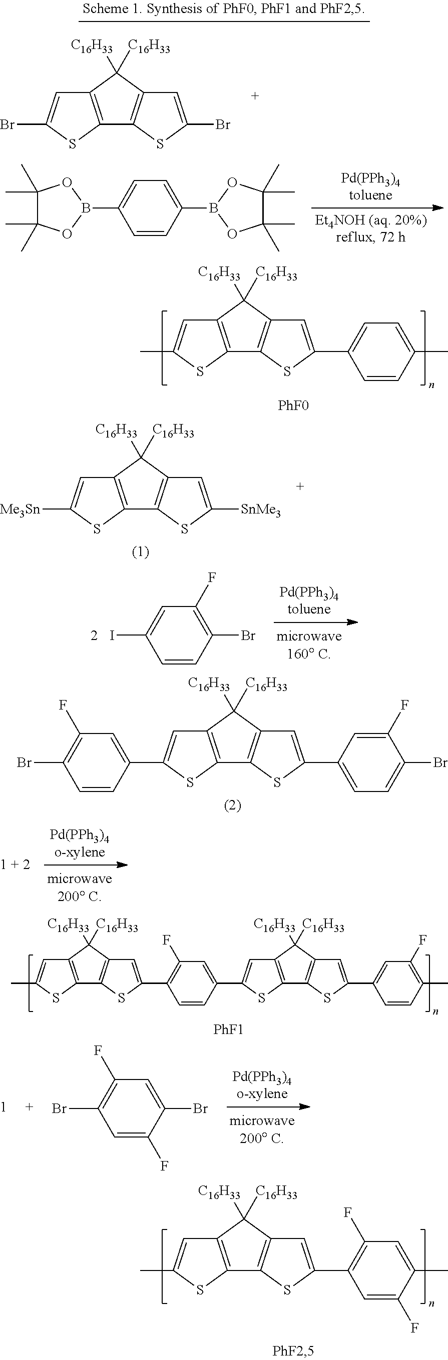

Scheme 1 shows examples of polymer synthesis. PhF0 is obtained by Suzuki cross-coupling from 2,6-dibromo-4,4-dihexadecyl-4H-cyclopenta[1,2-b:5,4-b′]dithiophene and 1,4-benzenediboronic acid dipinacol ester under the catalyst of Pd(PPh₃)₄ and the base of tetraethyl amine hydroxide (a.q. 20%) using toluene as the solvent, refluxing for 72 hours. This polymerization provides a number average molecular weight (Ma) of 23 kDa and a polydispersity index (PDI) of 2.3. Stille cross-coupling was also used to synthesize this polymer using 2,6-bistrimethylstanyl-4,4-dihexadecyl-4H-cyclopenta[1,2-b:5,4-b′]dithiophene (1) and 1,4-diiodobenzene, but the Mₙ was lower than 10 kDa. The inventors note that the asymmetric mono-fluorine substituted phenylene might create a regioirregular polymer by direct polymerization using 2,6-bistrimethylstanyl-4,4-dihexadecyl-4H-cyclopenta[1,2-b:5,4-b′]dithiophene (1) and 1,4-dibromo-2-fluorine-benzene; hence, a symmetric monomer 2 was first synthesized using compound 1 and 2 equivalent of 3-fluoro-4-iodobromobenzene.^{10,13} Then, the regioregular polymer PhF1 is achieved from monomer 1 and 2 using Pd(PPh₃)₄ as the catalyst and o-xylene as the solvent under microwave-assisted Stille polymerization at 200° C. This condition provides a Mₙ of 25 kDa and PDI of 2.4. The di-fluorine substituted polymer PhF2,5 is obtained from monomer 1 and 1,4-dibromo-2,5-difluo-benzene under the same polymerization condition as for PhF1. The Mₙ is 68 kDa and PDI is 2.7. Differential scanning calorimetry (DSC) shows that the melting points are 300° C. for PhF0, 285° C. PhF1, and 335° C. for PhF2,5, respectively (Figure S3 in Appendix B of U.S. Provisional Patent Application No. 62/327,311, entitled “NOVEL WEAK DONOR-ACCEPTOR CONJUGATED COPOLYMERS FOR FIELD-EFFECT TRANSISTOR APPLICATIONS” by G C. Bazan and M. Wang, cross-referenced above and incorporated by reference herein).

### 2. Characterization of the Copolymers Fabricated According to Scheme 1

(i) Absorption Measurements

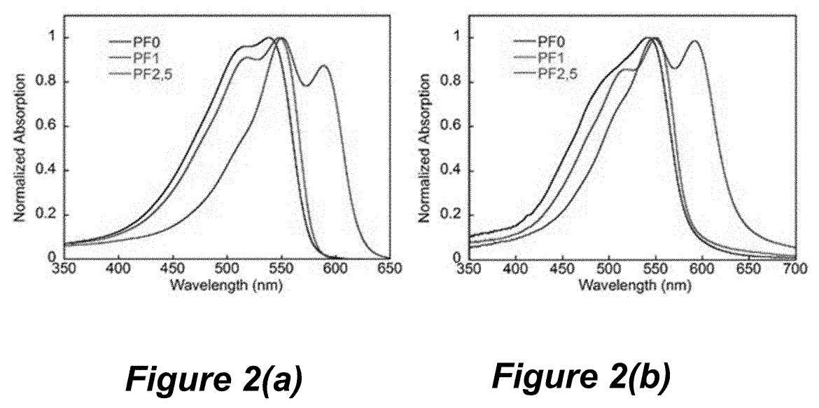

Solution and thin film UV-vis absorption are shown in FIGS. 2(a)-2(b). In chlorobenzene solution, the PhF0 data shows a π-π* transition peak at 519 nm and a shoulder peak at 538 nm. The PhF1 data shows a slight red-shift relative to the PhF0 data, with a π-π* transition peak at 519 nm and a shoulder peak at 548 nm. The PhF2,5 data shows significantly red-shifted absorption, with a π-π* transition peak at 550 nm and a shoulder peak at 589 nm. There is no obvious intramolecular charge transfer transition peak as the inventors observed for strong D-A polymers. In thin films, the PhF0 data shows a maximum peak at 542 nm, and the PhF1 data shows a π-π* transition peak at 518 nm and a shoulder peak at 551 nm. Similar to the solution absorption, the PhF2,5 data shows substantially red-shifted absorption relative to the PhF0 and the PhF1 absorption, with a π-π* transition peak at 548 nm and a shoulder peak at 592 nm. The inventors note that shoulder peaks in absorption profiles usually indicate aggregations.¹⁴ However, π-π stacking diffraction peaks are not observed in the X-ray scattering measurements of the PhF0 and PhF1 thin film examples discussed below. The driving force for such shoulder peaks in PhF0 and PhF1 is not clear yet. For solution UV-vis performed at 100° C. (Figure S2 in Appendix B of U.S. Provisional Patent Application No. 62/327,311, entitled “NOVEL WEAK DONOR-ACCEPTOR CONJUGATED COPOLYMERS FOR FIELD-EFFECT TRANSISTOR APPLICATIONS” by G. C. Bazan and M. Wang, cross-referenced above and incorporated by reference herein), a weak shoulder peak in data obtained for the PhF2,5 in solution was observed while no shoulder peaks in the data for the PhF0 and PhF1 solutions were observed. This indicates that the aggregation of PhF2,5 is much stronger than that of PhF0 and PhF1, which is reasonable considering that there are more fluorine atoms in PhF2,5, resulting in stronger non-bonding interactions. Their thin film bandgaps are calculated from the absorption onset. PhF0 and PhF1 data have a similar bandgap of 2.10 eV while PhF2,5 has a smaller bandgap of 1.95 eV. It is noted that these bandgap values are much greater than the bandgap values of CDTBTZ, P2 and P2F (1.1-1.3 eV).

(ii) Cyclic Voltammetry Measurements

Cyclic voltammetry was used to measure the energy levels¹⁵ and the results are shown in Figure S4, SI. Highest occupied molecular orbital (HOMO) levels are estimated from the oxidation onsets. PhF0 data shows the PhF0 having a HOMO level of about −5.1 eV. When fluorine atoms are introduced to the phenyl, the resulting polymers PhF1 and PhF2,5 both display a deeper HOMO level of about −5.2 eV. Their LUMO levels are calculated by adding thin film optical bandgaps to HOMO values, which are −3.0 eV for PhF0, −3.1 eV for PhF1, and −3.25 eV for PhF2,5 respectively. These LUMO levels are significantly higher than the LUMO levels for CDTBTZ and P2 (−3.5˜−4.0 eV, respectively), which increases the barrier to inject electrons from the gold electrodes.

(iii) Density Functional Theory (DFT) Calculations

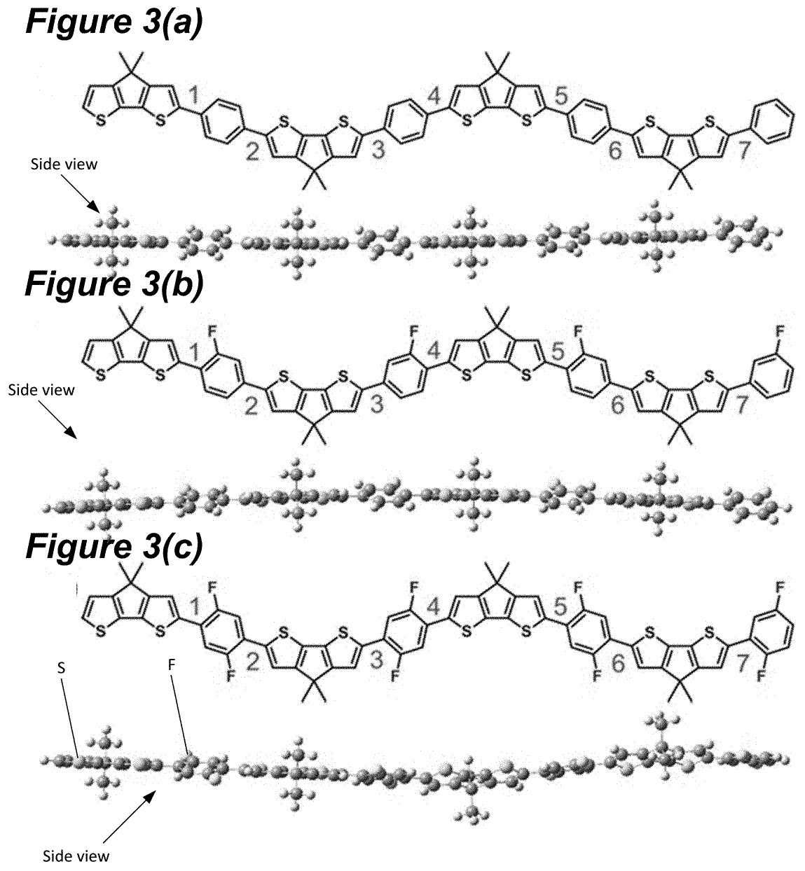

As mentioned above, the fluorine substitutions might change the preferred molecular conformations by a weak D-A interaction and F . . . H, F . . . S non-bonding interactions. Here, an initial study is performed using a DFT calculation at the B3LYP/6-311G(d,p) level of the theory, simplifying polymers to oligomers consisting of four CDT and phenylene units, substituting the hexadecyl sidechain with methyl to simplify the calculation, and wherein fluorine atoms are set to point to the CDT hydrogen atoms (as the F . . . H non-bonding interaction is greater relative to F . . . S non-bonding interactionsl^{12a}). The side view of each oligomer is provided in FIGS. 3(a)-3(c), and the planarity is quantified by calculating the average of seven absolute dihedral angles between adjacent CDT and phenyl units (Table S1 in Appendix B of U.S. Provisional Patent Application No. 62/327,311, entitled “NOVEL WEAK DONOR-ACCEPTOR CONJUGATED COPOLYMERS FOR FIELD-EFFECT TRANSISTOR APPLICATIONS” by G. C. Bazan and M. Wang, cross-referenced above and incorporated by reference herein). It is obvious that there is a twist between adjacent CDT and phenyl in the PhF0 backbone. The average absolute dihedral angle is 24.76°. With mono-fluorine substitution on the phenyl, the backbone planarity of PhF1 oligomer is enhanced slightly relative to the PhF0 oligomer, the PhF1 having an average absolute dihedral angle of 21.92°. With di-fluorine substitution on the phenyl, the backbone of the PhF2,5 oligomer displays significantly improved planarity relative to PhF0, the PhF2,5 having an average absolute dihedral angle decreasing to 16.190. Note that this is a single molecule simulation in vacuum. The planarity should influence the intermolecular packing in aggregates. Based on the above concerns, PhF2,5 would be considered a more favorable candidate for forming well-ordered aggregates in the solid state while PhF0 and PhF1 may not.

### 3. Characterization of OFET Devices Comprising the Copolymers Fabricated According to Scheme 1

Bottom-contact, bottom-gate OFETs were fabricated using devices with the following top-to-bottom architecture: polymer/Au/SAM/SiO₂/Si (doped). Decyltrichlorosilane (DTS) was used as the self-assembled monolayer (SAM) on the silicon oxide substrate. Thin films were prepared via doctor-blading, and films were annealed at 200° C. Devices were tested under nitrogen. The complete details are provided in Appendix B of U.S. Provisional Patent Application No. 62/327,311, entitled “NOVEL WEAK DONOR-ACCEPTOR CONJUGATED COPOLYMERS FOR FIELD-EFFECT TRANSISTOR APPLICATIONS” by G. C. Bazan and M. Wang, cross-referenced above and incorporated by reference herein).

(i) Device Performance

TABLE 1
Mobilities, on/off ratios, and Vₜ of OFET devices.

| Polymer | Mobility (cm²V⁻¹s⁻¹) | On/off | Vₜ(V) |
|---|---|---|---|
| PhF0 (R.T.) | 0.0004 | 1.7 × 10³ | −4.9 |
| PhF1 (R.T.) | 0.0013 ± 0.0006 | 6.0 × 10³ | −10.2 |
| PhF1 (200° C.) | 0.0018 ± 0.0002 | 4.6 × 10³ | −10.9 |
| PhF2,5 (R.T.) | 0.039 ± 0.028 | 9.7 × 10⁴ | −15.4 |
| PhF2,5 (200° C.) | 0.68 ± 0.18 | 1.7 × 10⁶ | −5.7 |

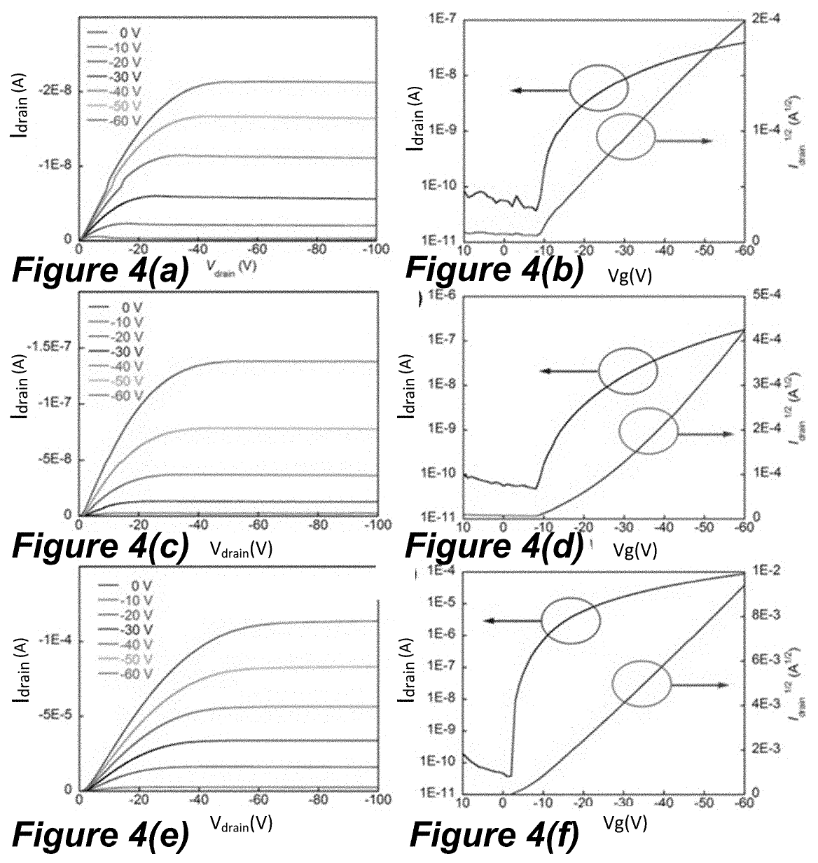

Output curves are shown in FIGS. 4(a), 4(c) and 4(e). The drain currents (I_{drain}) are saturated when the drain voltage (V_{drain}) is greater than −60 V and show unipolar p-type transport characteristics. As shown in FIGS. 4b, 4d and 4f, transfer curves are collected from the first scan of current-voltage characteristics under a V_{drain} of −80 V to obtain mobilities in the saturated region. The mobilities are calculated from the slope of the I_{drain}^{1/2} vs gate voltage (V_{g}) curves. Table 1 shows the average mobilities, together with the corresponding average on/off ratios and threshold voltages (Vₜ) for devices as cast at room temperature (r.t.) and annealed. Individual device mobilities are provided in Appendix B of U.S. Provisional Patent Application No. 62/327,311, entitled “NOVEL WEAK DONOR-ACCEPTOR CONJUGATED COPOLYMERS FOR FIELD-EFFECT TRANSISTOR APPLICATIONS” by G C. Bazan and M. Wang, cross-referenced above and incorporated by reference herein. At r.t, PhF0 devices have an average mobility of 0.0004 cm²V⁻¹s⁻¹. With mono fluorine substitution, PhF1 devices have an average mobility of 0.0013±0.0006 cm²V⁻¹s⁻¹, which is slightly higher than for PhF0 devices. With two fluorine substitutions, PhF2,5 devices have an average mobility of 0.039±0.028 cm²V⁻¹s⁻¹, which is two orders higher relative to PhF0 devices. When these devices are annealed at 200° C., PhF0 devices have almost no mobility (Table S3, in Appendix B of U.S. Provisional Patent Application No. 62/327,311, entitled “NOVEL WEAK DONOR-ACCEPTOR CONJUGATED COPOLYMERS FOR FIELD-EFFECT TRANSISTOR APPLICATIONS” by G C. Bazan and M. Wang, cross-referenced above and incorporated by reference herein), with I_{drain} approaching the gate leakage current, and PhF1 device mobilities are identical (to within an order of magnitude) to the r.t. devices. PhF2,5 devices have an average mobility of 0.68±0.18 cm²V⁻¹s⁻¹ and a maximum mobility of 0.92 cm²V⁻¹s⁻¹, which is on the same order of mobility as the mobility for strong D-A copolymers obtained based on non-aligned devices.^{10,16} The mobility correlates with the number of fluorine substitutions (consistent with DFT calculation results which suggest that the more fluorine substitutions, the better planarity of the polymer backbone, leading to longer conjugation length and better film organizations that ultimately would give greater mobility). There have been reports that the molecular weight might influence the mobility.^{4c,17} However, typically a molecular weight difference in the range of 20-70 kDa would not lead to such a big change in mobility. In addition, as discussed below, the inventors have observed film organization that changes completely and that is less influenced by molecular weight.¹⁸ It is more likely in the cases presented here that the structure planarity plays a key role while molecular weight has less influence.

(ii) Device Morphology

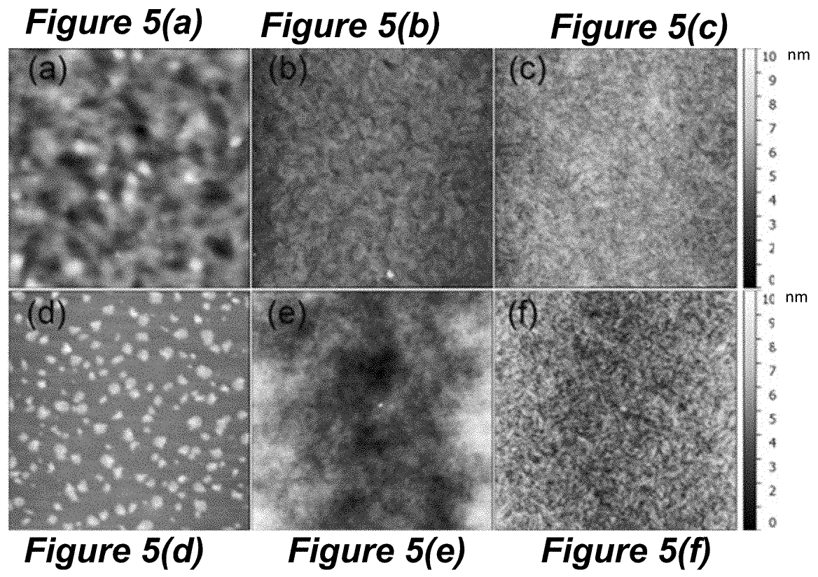

Atomic force microscopy (AFM) was used to investigate surface topographical features of the devices. Height images are shown in FIGS. 5(a)-5(f). Their 3D images are provided in Figure S8 of Appendix B of U.S. Provisional Patent Application No. 62/327,311, entitled “NOVEL WEAK DONOR-ACCEPTOR CONJUGATED COPOLYMERS FOR FIELD-EFFECT TRANSISTOR APPLICATIONS” by G C.

Bazan and M. Wang, cross-referenced above and incorporated by reference herein. As shown in FIG. 5(a), the PhF0 film forms a rough topographic surface with a large root mean square (RMS) roughness of 10.46 nm, but the polymer domain is still continuous on the substrate. As shown in FIGS. 5(b) and 5(c), both PhF1 and PhF2,5 films are continuous and smooth on the substrates. Their RMS roughnesses are 0.93 nm for PhF1 and 1.65 nm for PhF2,5, respectively. As shown in FIG. 5(d), after annealing at 200° C., PhF0 films form isolated domains that may inhibit charge transport pathways. This morphology is consistent with the decrease in mobility. As shown in FIGS. 5(e) and 5(f), PhF1 and PhF2,5 films both exhibit slightly increased roughness relative to that without annealing. Their RMS roughness values are about 1.14 nm for PhF1 and 1.91 nm for PhF2,5. Moreover, FIGS. 5(e) and 5(f) show a PhF2,5 film has structured domains while the PhF1 film shows regions with more amorphous characteristics. The annealing morphologies indicate that the thermal morphology stability is better in the polymer with more fluorine substitutions.

### 4. Crystallinity of Films Comprising the Copolymers Fabricated According to Scheme 1

Grazing-incidence wide-angle X-ray scattering (GIWAXS) was used to investigate thin film organization.¹⁹ The two dimensional (2D) diffraction images, obtained using Nika software,²⁰ are provided in Appendix B of U.S. Provisional Patent Application No. 62/327,311, entitled “NOVEL WEAK DONOR-ACCEPTOR CONJUGATED COPOLYMERS FOR FIELD-EFFECT TRANSISTOR APPLICATIONS” by G C. Bazan and M. Wang, cross-referenced above and incorporated by reference herein. PhF0 and PhF1 pristine films and annealed films scatter weakly, only showing either an amorphous scattering halo or a single scattering peak.

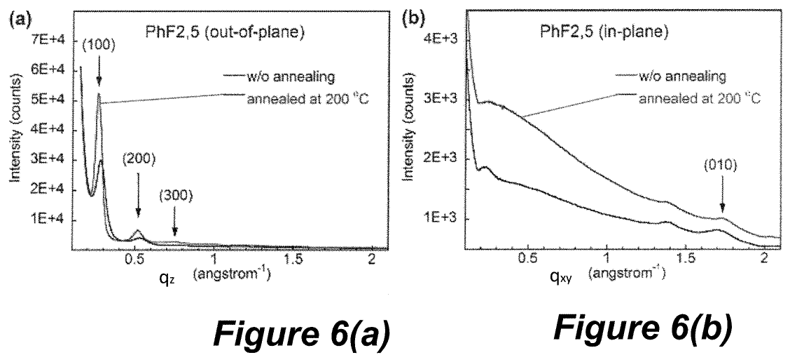

These results are consistent with the observations made in the DFT calculation and mobility testing discussed above. To the contrary, the PhF2,5 film exhibits clear diffraction peaks at r.t., which are more pronounced after thermal annealing. The line-cut profiles of PhF2,5 are shown in FIG. 6. From the annealed film, in the out-of-plane direction, there is a strong peak around 0.27 Å⁻¹ and a peak around 0.52 Å⁻¹ corresponding to the 2^{nd} order; these are assigned to alkyl chain stacking features with a stacking distance of 2.36 nm. After annealing, a rise in the 3^{rd} order peak is also observed. In the in-plane direction, there is a strong peak around 1.75 Å⁻¹, which is assigned to π-π stacking with a stacking distance of 3.58 Å. These features indicate that the PhF2,5 film presents an edge-on orientation relative to the substrate normal. In addition, it is interesting that these thin film organization features (orientation, alkyl stacking and π-π stacking) are similar to that of CDTBTZ, P2 and P2F films, which proves the utility of the present disclosure's material design strategy using a polymer backbone similar to strong D-A copolymers while enhancing intra- and inter-chain interactions via fluorine substitutions for desirable thin film organizations.

In summary, the three novel wide bandgap polymers synthesized according to Scheme 1 have desirable properties for OFET applications. The backbone planarity of PhF2,5 is greatly enhanced relative to PhF0 and PhF1. PhF2,5 shows well-ordered film organization in the AFM and GIWAXS measurements and exhibits an average mobility 0.68±0.18 cm²V⁻¹s⁻¹ together with high on/off ratio when fabricated in devices. Moreover, PhF2,5 is a relatively wide bandgap polymer having high-lying LUMO levels in comparison with previously reported strong D-A copolymers (CDTBTZ, P2, P2F, PDF) despite sharing a similar polymer backbone to these strong D-A copolymers. These results show that PhF2,5 is a promising polymer and the material design strategy described herein is significant for future OFET material synthesis.

### 5. Second Synthesis Example (Scheme 2)

The following copolymers were also synthesized (using Scheme 2) and characterized in OFET devices.

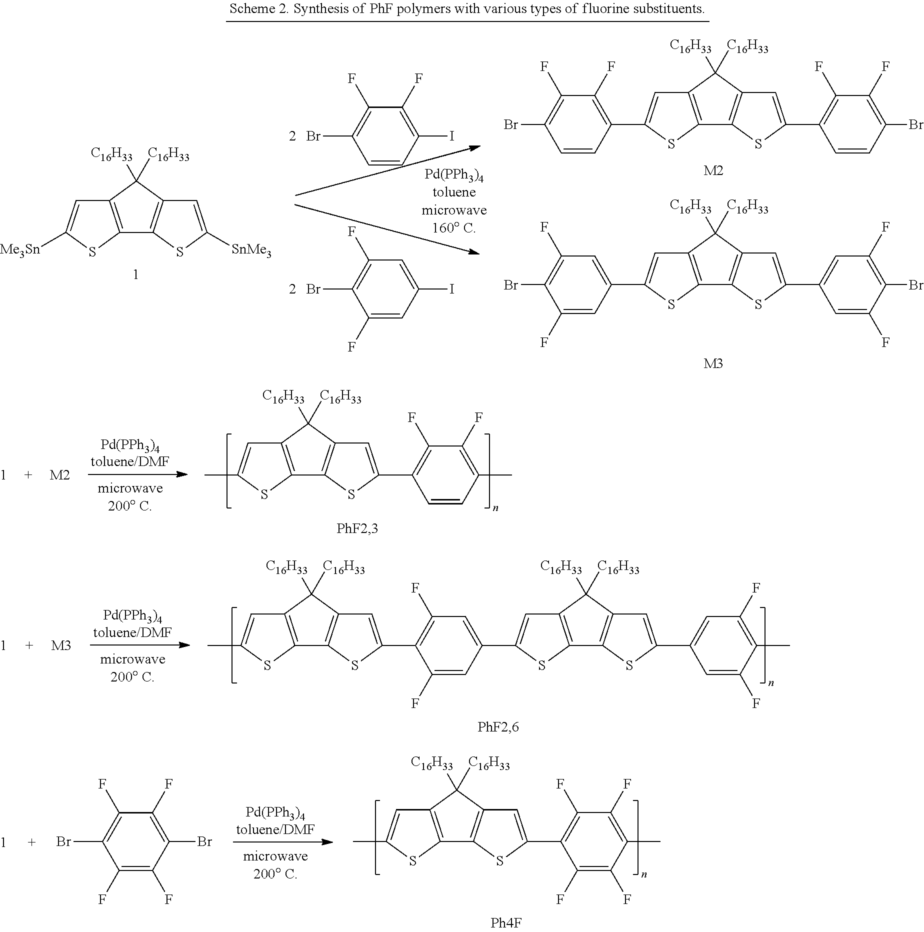

TABLE 2
OFET mobility of PhF2,3, PhF2,6 and Ph4F devices
without nano-groove substrates.

| | Mobility | Vₜ | |
|---|---|---|---|
| polymer | (cm²V⁻¹s⁻¹) | (V) | On/off |
| PhF2,3 | 0.9 | 1.6 | 9.8 × 10⁵ |
| PhF2,6 | 0.7 | 4.2 | 1.3 × 10⁶ |
| Ph4F | 0.05 | 10 | 1.3 × 10⁴ |

TABLE 3
OFET mobility of PhF2,3, PhF2,6 and PhF2,5 devices
with nano-groove substrates.

| | Mobility | Vₜ | |
|---|---|---|---|
| polymer | (cm²V⁻¹s⁻¹) | (V) | On/off |
| PhF2,3 | 1.8 ± 0.5 | −8.5 | 1.9 × 10⁶ |
| PhF2,6 | 3.1 ± 0.5 | −12.0 | 3.6 × 10⁶ |
| PhF2,5 | 2.2 ± 0.3 | −9.9 | 2.4 × 10⁶ |

### 6. Third Synthesis Example: Synthesis of Small Molecules

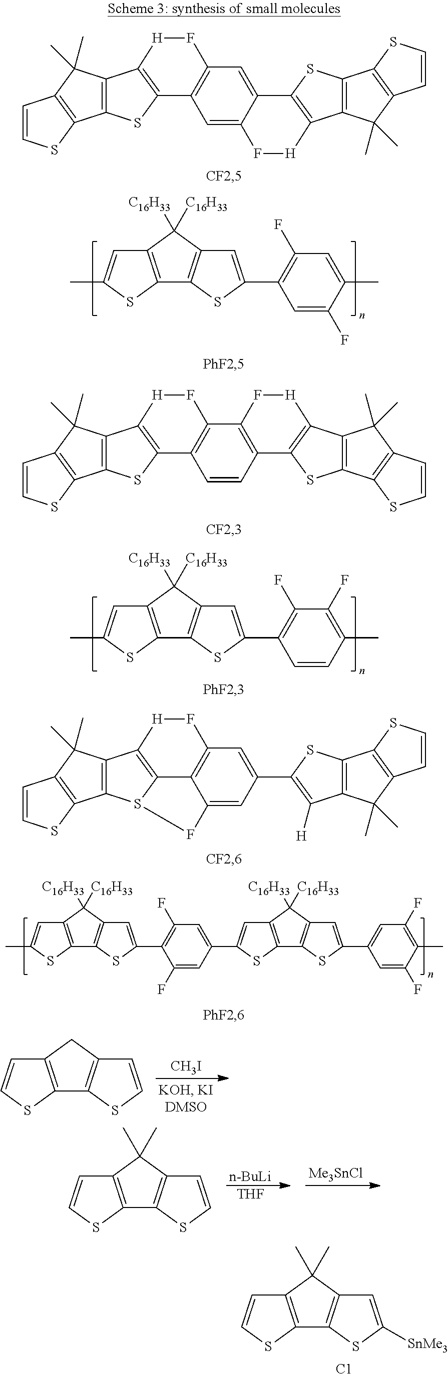

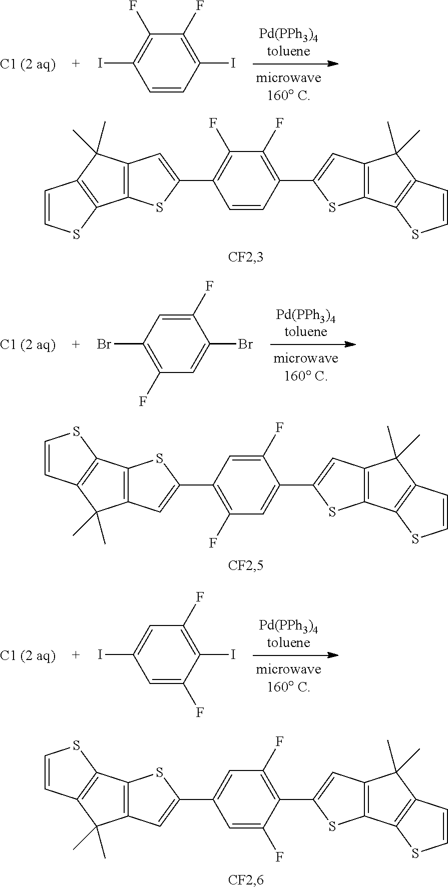

Scheme 3 shows the synthesis of three small molecule regio-isomers (CF2,3, CF2,5 and CF2,6). The wing precursor 2-trimethylstanyl-4,4-dimethyl-4H-cyclopenta[2,1-b:3,4-b′]dithiophene (C1) was synthesized from the cyclopenta[2,1-b:3,4-b′]dithiophene via the standard alkylation and stannylation according to previously reported methods.³⁰ Relevant core precursors (2,3-difluoro-1,4-diiodobenzene, 2,5-difluoro-1,4-dibromobenzene and 3,5-difluoro-4-bromoiodobenzene) are obtained from Sigma-Aldrich Co. without further purification. Then three regio-isomers were synthesized via Stille coupling using the catalytic Pd(PPh₃)₄ in toluene solution under microwave heating at 160° C. These regio-isomers were purified via silica-gel column, and their single crystals were obtained in a chloroform/methanol co-solvent system under a very slow evaporation process.

### 7. Fourth Synthesis Example: Synthesis of Polymeric Regio-Isomers

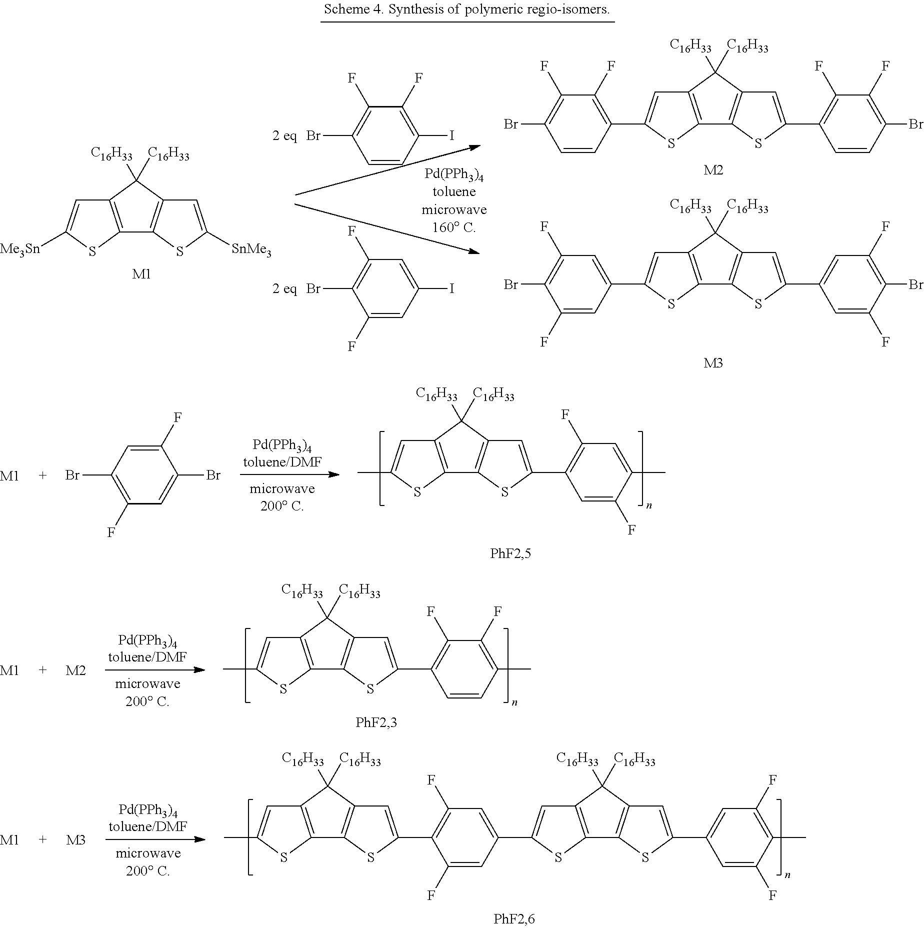

Scheme 4 outlines the synthesis of the three polymers studied here. The polymer PhF2,5 was synthesized via a previously reported method³¹ using M1 (same as monomer 1 in scheme 1 and scheme 2) and 2,5-difluoro-1,4-dibromobenzene under the microwave-assisted Stille polycondensation with the catalytic Pd(PPh₃)₄ in o-xylene solution at 200° C. for 40 minutes. Under this condition, an average molecular weight (M) of 28 kDa and a polydispersity index (D) of 2.1 were obtained, which is measured by gel permeation chromatography (GPC) at 150° C. using 1,2,4-trichlorobenzene as the eluent and polystyrene as the standard. This polymerization condition was used to synthesize the PhF2,3 directly using M1 and commercially available 2,3-difluoro-1,4 diiodobenzene, but the molecular weight was not high enough. To achieve a comparable Mₙ as PhF2,5, monomer M2 containing two DFPh units and a CDT unit was first synthesized. Then, the polymerization was performed using M1 and M2, which provided a Mₙ of 34 kDa and a D of 2.0. PhF2,6 is a regioregular polymer with two adjacent 2,6-difluoro-1,4-diphenylene units symmetrically located on both sides of CDT units. A symmetric monomer M3 was first synthesized by carrying out the Stille reaction using M1 and 2 eq of 3,5-difluoro-4-bromoiodobenzene, then Ph2,6 is obtained using M3 and M1 using similar polymerization conditions as for synthesizing of PhF2,5, which provide a Mₙ of 33 kDa and a D of 2.3. Their molecular weight variations are small which should minimize the molecular weight impact on the morphology and performance.³²

(i) Structure Conformations

TABLE 4
Torsional angles and molecule distances of CF2,3,
CF2,5 and CF2,6 from their single crystals.

| | CF2,3 | CF2,5 | CF2,6 |
|---|---|---|---|
| Torsional angle (°) | 16.4 | 17.1 | 17.0 |
| Packing distance (Å) | 3.83 | 3.70 | 3.77 |

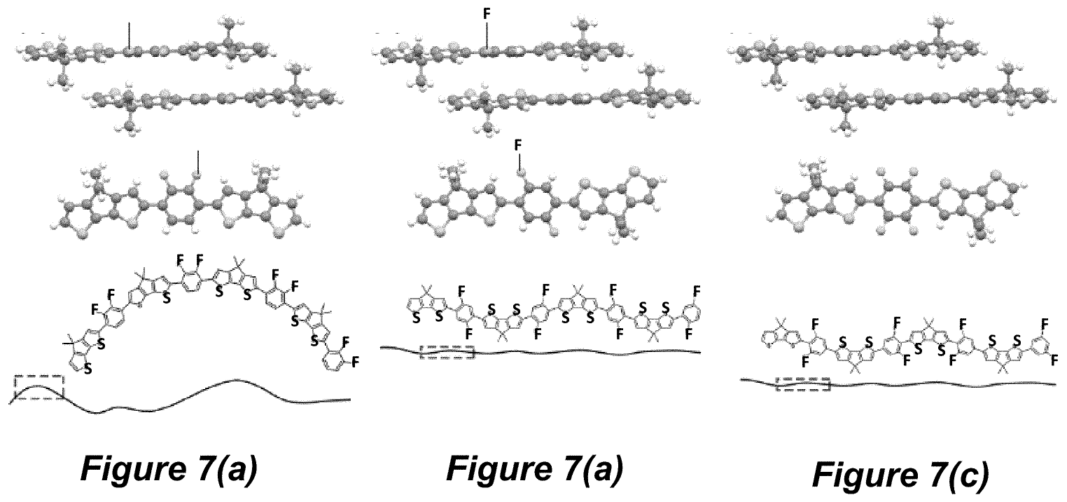

As shown in FIGS. 7(a)-7(c), single crystals of CF2,3, CF2,5 and CF2,6 were obtained and analyzed to provide the exact structure information. These results consider the most favorable conformations of CDT unit and adjacent DFPh units. Torsional angles between CDT unit and DFPh units and the adjacent molecules packing distances are shown in Table 4. These torsional angles are nearly the same at ˜16°-17°. In addition, their adjacent planes packing distances are also similar at about 3.7-3.8 Å. It is also interesting that methyl groups of two CDT units are on the same side (cis) in CF2,3 molecule while these methyl groups are located on both sides (trans) in CF2,5 and CF2,6.

First, the above information suggests that the F . . . H non-bonding interaction strongly influences the molecule conformation of these small molecules, epitomized by the three fluorine regio-substitution versions resulting in different molecule shapes. It is reasonable that the above configurations would also be more favorable in each polymer backbone.³³ FIGS. 7(a)-7(c) show two neighboring CDT units prefer to form a cis conformation in the PhF2,3 backbone, and therefore the backbone is proposed to contain more curved species while PhF2,5 and PhF2,6 backbones are proposed to have a linear shape (as their neighboring two CDT units prefer to form a trans conformation). Theoretical calculations of three tetramers in FIGS. 7(a)-7(c) were also performed, and the results proved that above proposed conformations are most stable in the gas phase. As a result, the PhF2,3 self-assembling behavior should be different to PhF2,5 and PhF2,6 because the backbone curvature play an important role on the adjacent chains fitting via both alkyl chain and π-π stacking.³⁴

Second, the degree of F . . . H non-bonding interaction also need to be taken into consideration. PhF2,5 contains more F . . . H non-bonding interactions relative to PhF2,6, which suggests that the PhF2,5 backbone would be more rigid due to a two-fold advantage of F . . . H lock formations.³⁵ For PhF2,3 backbone, the degree of F . . . H lock formations can be considered to less than that of PhF2,5 since a small portion of CDT or DFPh units might be flipped to avoid a spiral-like shape of the polymer backbone. Combining these two factors, it is thought that PhF2,5 would be the most favorable structure to form well-ordered aggregates via adjacent polymer chains packing while PhF2,3 would be the least desirable structure to form well-ordered aggregates. These predictions of polymer features are based on the F . . . H impact on single crystal structure of the smallest structure piece, and the following experiments examine these hypotheses and their influence on charge-carrier p of corresponding polymers.

(ii) Absorption, Thermal Transition and Energy Levels

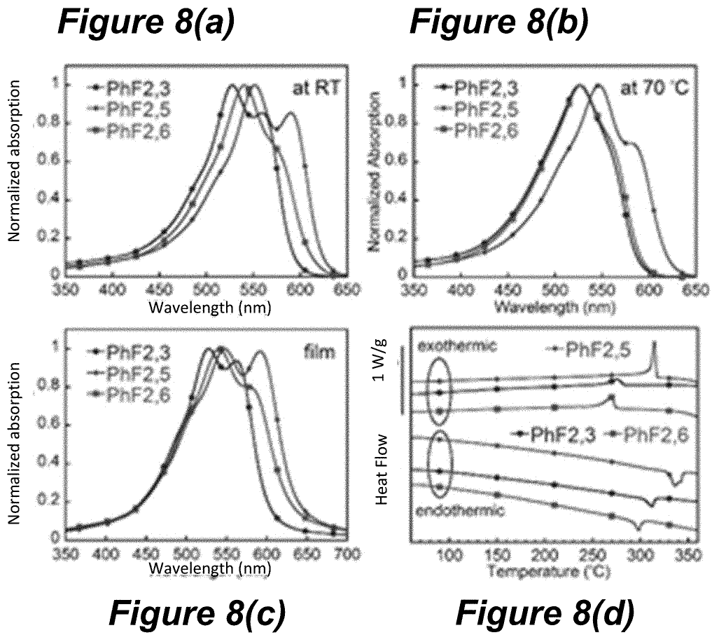

UV-vis absorption was used to study the regio-influence on the optical properties. FIG. 8(a) shows polymer solutions (0.01 mg/mL, in chlorobenzene) absorbance at room temperature. PhF2,3 has a π-π* transition peak at 527 nm and an obvious shoulder peak at 560 nm. PhF2,6 shows a red-shifted π-π* transition peak at 540 nm together with a weak shoulder absorbance relative to PhF2,3. PhF2,5 displays a π-π* transition peak at 552 nm and a significant shoulder peak at 590 nm. FIG. 8b shows polymer solution absorbance at 70° C. using same solutions. PhF2,3 and PhF2,6 display a similar maximum absorption peak around 526 nm while PhF2,5 has a maximum absorption peak at 547 nm. In PhF2,3 hot solution, the shoulder peak has almost disappeared. Interestingly, in PhF2,6 hot solution, there is still a weak shoulder hump indicating a low degree of aggregates of PhF2,6 polymer chains. Moreover, in PhF2,5 hot solution, an obvious absorption shoulder remains around 581 nm, which indicates that the PhF2,5 aggregates are much more resistant to heating relative to PhF2,3 and PhF2,6. This phenomenon is consistent with the above hypothesis from the single crystal conformations, which suggested that the linear small molecule structure would extend to linear conformations in the polymer and lead to enhanced chain-to-chain packing. FIG. 8c shows polymer thin film absorbance. PhF2,3 displays a π-π* transition peak at 528 nm together with a shoulder peak at 562 nm. PhF2,6 displays a π-π* transition peak at 541 nm together with a shoulder peak at 580 nm. PhF2,5 displays a π-π* transition peak at 547 nm together with a shoulder peak at 592 nm. It is also noted that these shoulder peaks in thin film are more pronounced relative to those in solution at rt, which indicates that better order organizations are obtained in thin film than that in solution. Their optical band-gaps (E_{g}) were calculated from their film absorption onset. PhF2,5 has an E_{g} of 1.94 eV. PhF2,6 have a similar E_{g} of 1.96 eV while PhF2,3 has the largest E_{g} of 2.05 eV.

Differential scanning calorimetry (DSC) is used to determine the phase thermal transitions. As shown in FIG. 8(d), all polymers display clear melting points (Tₘ) and crystallization points (T), which are Tₘ=299° C., T_{c}=269° C. for PhF2,6, Tₘ=312° C., T_{c}=275° C. for PhF2,3 and Tₘ=337° C., T_{c}=315° C. for PhF2,5 respectively. Interestingly, melting and crystallization trends seem to correlate with the degree of F . . . H formations, probably due to the F . . . H lock formation dominating the polymer backbone rigidity and influencing the chain movements (and then PhF2,5 is mostly influenced). In addition, it is shown that the crystallization peak of PhF2,5 is significantly stronger than that of PhF2,3 and PhF2,6, which also suggests that F . . . H non-bonding interactions in PhF2,5 are more efficient in locking the backbone.

Cyclic voltammetry (CV) is used to measure the energy levels. Highest occupied molecular orbital (HOMO) levels are estimated from the oxidation onsets. PhF2,3 and PhF2,6 show a similar HOMO level of about −5.30 eV which is deeper than that of PhF2,5 (−5.25 eV). Their LUMO levels are calculated by adding thin film E_{g} to HOMO values, which give LUMO values: E_{LUMO}=−3.25 eV for PhF2,3; E_{LUMO}=−3.30 eV for PhF2,5 and E_{LUMO}=−3.35 eV for PhF2,6. These LUMO level values indicate there is a large barrier to inject electrons from the gold electrodes, which optimize these polymers for unipolar p-type transistors.³⁶

(iii) OFET Devices

Bottom-contact, bottom-gate OFETs were fabricated using devices with the following top-to-bottom architecture: polymer/Au/Ni/SAM/SiO₂/Si (doped). Decyltrichlorosilane (DTS) was used as the self-assembled monolayer (SAM) on the silicon oxide substrate. Thin films were prepared via doctor-blading from chlorobenzene solution at 5 mg/ml. Both solution and substrate were preheated at 70° C. before casting. The coating speed was set to 0.1 mm/s. Film thickness is about 100 nm using the above conditions. Films were then annealed at 200° C. for 10 minutes. Devices were tested under nitrogen.

TABLE 5
Mobilities, on/off ratios and Vₜ of OFET devices.

| | | μ | | Vₜ |
|---|---|---|---|---|
| polymer | NG | (cm²V⁻¹s⁻¹) | On/off | (V) |
| PhF2,3 | No | 0.85 ± 0.22 | 9.8 × 10⁵ | 1.6 |
| | Parallel | 1.9 ± 0.3 | 1.9 × 10⁶ | −5.9 |
| | Perpendicular | 0.12 ± 0.01 | 1.8 × 10⁵ | −7.5 |
| PhF2,5 | No | 0.63 ± 0.24 | 1.4 × 10⁶ | 7.1 |
| | Parallel | 2.3 ± 0.4 | 2.4 × 10⁶ | −0.8 |
| | Perpendicular | 0.14 ± 0.06 | 2.6 × 10⁵ | 1.8 |
| PhF2,6 | No | 0.69 ± 0.22 | 1.3 × 10⁶ | 4.2 |
| | Parallel | 3.1 ± 0.5 | 3.6 × 10⁶ | 3.7 |
| | Perpendicular | 0.12 ± 0.01 | 1.9 × 10⁵ | −3.3 |

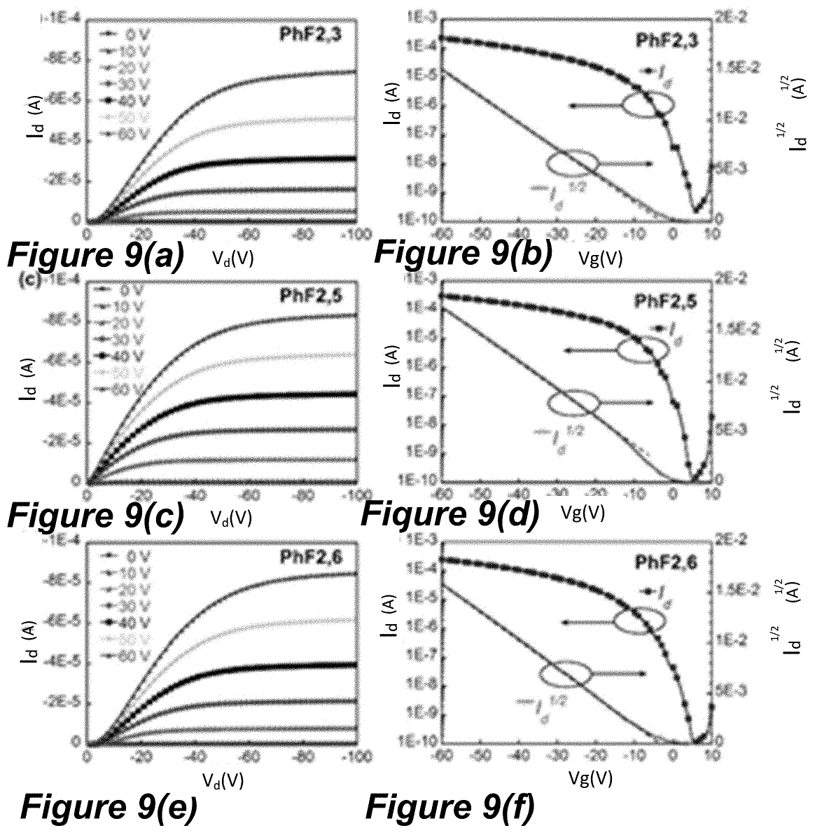

First, the devices using normal substrates were characterized. Output curves are shown in FIGS. 9(a), 9(c) and 9(e). The drain current (I_{d}) is saturated when the drain voltage (V_{d}) is greater than −60 V and shows unipolar p-type transport characteristics. As shown in FIG. 9(b), 9(d) and 9(f), transfer curves are collected from the first scan of current-voltage characteristics under a V_{d} of −80 V to obtain mobilities in the saturated region. The mobilities are calculated from the slope of I_{d}^{1/2} vs. gate voltage (V_{g}) curves. Table 5 provides average p, together with the corresponding average on/off ratios and threshold voltages (V). PhF2,3 devices have an average p of 0.85±0.22 cm²V⁻¹s⁻¹. PhF2,5 devices have an average p of 0.63±0.24 cm²V⁻¹s⁻¹. PhF2,6 devices have an average p of 0.69±0.22 cm²V⁻¹s⁻¹. In addition, their on/off ratios are all on the order of 10⁶ which is remarkably high. Interestingly, the device performance difference among the three polymers is within the error using regular device fabrication, though polymer chain aggregations in solution differ significantly.

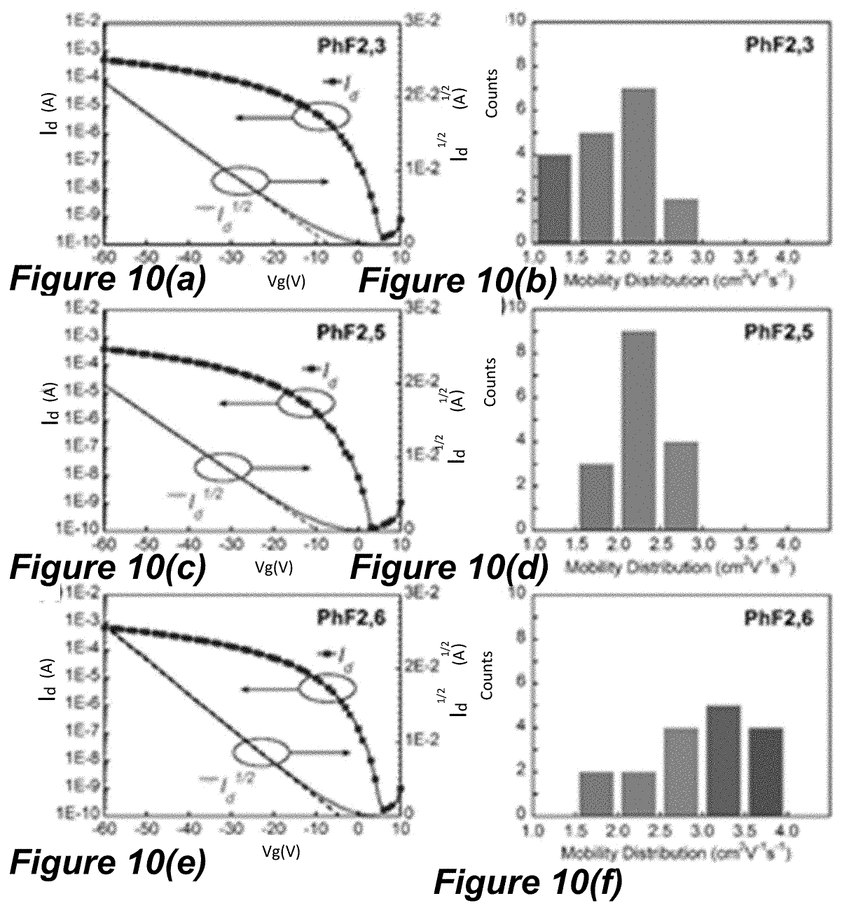

Second, thin films were blade coated using the built-in nanogroove (NG) substrates under the same film processing conditions. Three batches of NG substrates were fabricated to eliminate batch to batch variations of the NGs. FIGS. 10(a), 10(c) and 10€ provide the typical transfer curves for these devices. FIGS. 10(b), 10(d) and 10(f) show p distributions. As shown in Table 5, in the parallel direction, PhF2,3 devices have an average p of 1.9±0.3 cm²V⁻¹s⁻¹, polymer PhF2,5 devices have an average p of 2.3±0.4 cm²V⁻¹s⁻¹ and polymer PhF2,6 devices have an average p of 3.1±0.5 cm²V⁻¹s⁻¹. The highest p among all devices is achieved from PhF2,6, which is about 3.9 cm²V⁻¹s⁻¹. In addition, all devices show high on/off ratios on the order of 10⁶. Each device was scanned 20 times and in the multiple scan I-V characteristics, all devices show highly stable on/off current, indicating no adverse effects due to electron injection from the gold electrode to the semiconductor. This feature highlights the importance of designing high LUMO levels for the polymer semiconductors for unipolar p-type OFETs. Table 5 also provides the perpendicular direction mobilities, which are u=0.12±0.01 cm²V⁻¹s⁻¹ for PhF2,3, p=0.14±0.06 cm²V⁻¹s⁻¹ for PhF2,5 and u=0.12±0.01 cm²V⁻¹s⁻¹ for PhF2,6.

It is noted that the devices' perpendicular mobilities values all have similar low values, which is attributed to the difficulty for regular charge hopping through polymer inter-chains within a polymer bundle, as well as the charge transport across the polymer bundles that is affected by the NGs.^{37b} Since the perpendicular mobility is complicated in the NG devices, only the average p improvement from non-NG devices was compared to parallel NG devices, which also provides an evaluation of the film alignment quality. Mobilities of all parallel devices are substantially enhanced relative to perpendicular devices and devices without NGs, which suggests that all these polymers could be aligned via NGs during the film formation process. For polymer PhF2,3, the p improves 120% via NG-assistant alignment, while enhancements are 270% for PhF2,5 and 350% for PhF2,6 respectively. Surprisingly and unexpectedly, the p distributions are more significant than devices without NGs, which indicates different alignment capabilities due to the different fluorine substitutions. As shown in FIGS. 10b, 10d and 10f, PhF2,6 devices had p over 3 cm²V⁻¹s⁻¹ while none of PhF2,3 and PhF2,5 devices obtained p over 3 cm²V⁻¹s⁻¹; on the contrary, only PhF2,3 shows low performing devices of p below 1.5 cm²V⁻¹s⁻¹. Since three polymers show similar p on the normal substrates, the degree of improvement suggests that the alignment quality of PhF2,6 film is the best, the alignment quality of PhF2,3 film is the worst and the alignment quality of PhF2,5 film is in between.

(ii) Film Morphologies

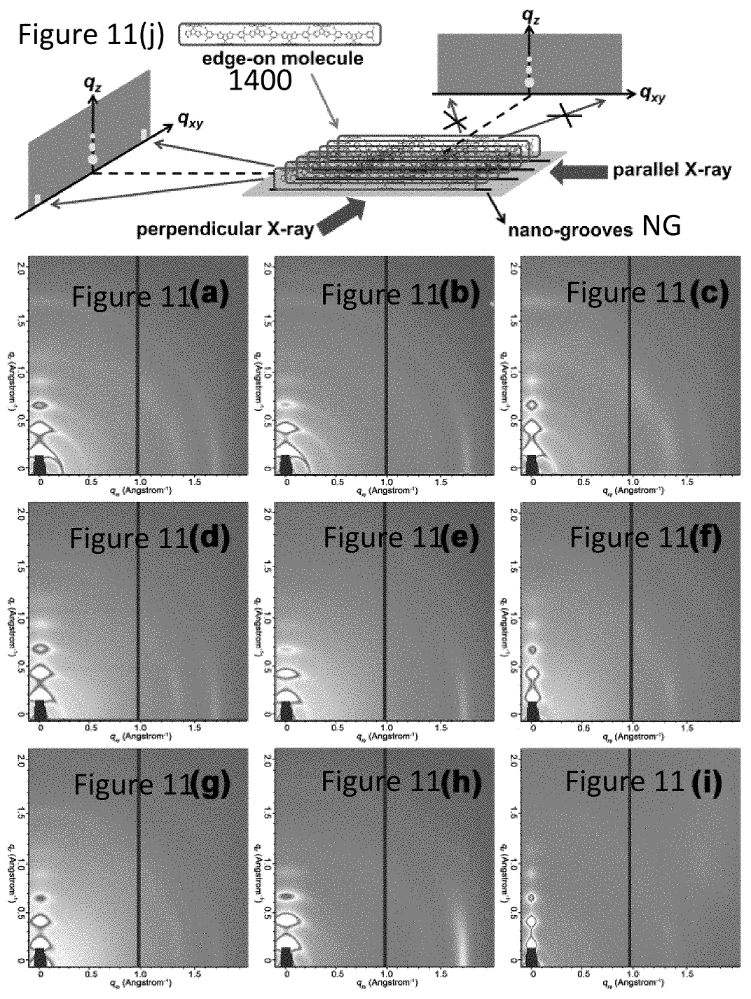

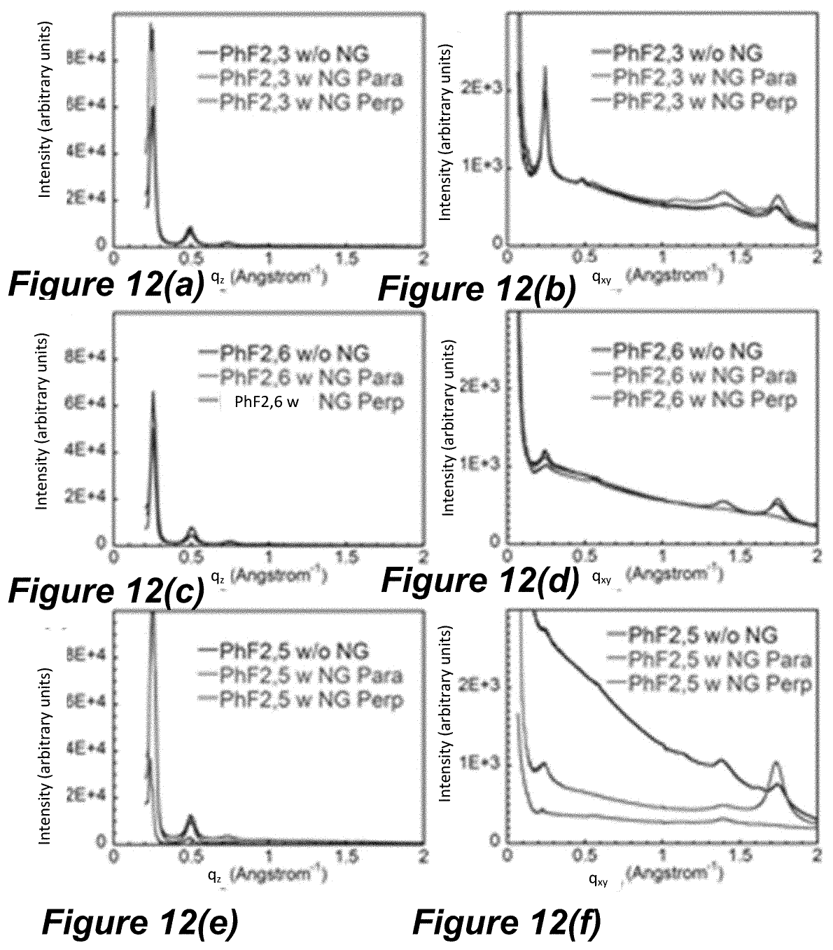

The film morphologies were evaluated by GIWAXS measurements. FIGS. 11(a)-11(j) show the GIWAXS set-up and 2D-images. Their line-cut profiles are provided in FIGS. 12(a)-12(f). Films were blade-coated using the same solution at 70° C., but using a fast coating speed of 1 mm/s to decrease the film thickness to ˜20 nm. At this thickness scale, the X-ray scattering could better collect the bottom layer information, which is expected to reveal information about alignment. Polymer aggregation should similarly impact the alignment as concentration and temperature are identical in two coating speeds. As shown in FIGS. 11(a), 11(d), 11(g), the scattering on the films using normal substrates was also collected. In the out-of-plane direction, these films all displayed similar peaks with q_{z}=0.25-0.26 Å⁻¹, corresponding to a distance of 2.5 nm, which is a typical stacking distance from hexadecyl side chain. For the in-plane direction, these films all displayed a similar peaks with q_{xy}=1.75 Å⁻¹, corresponding to a distance of 3.6 Å, which is within the π-π distance region. In addition, for polymer PhF2,3 film, the alkyl chain stacking peak weakly extends to in-plane direction, indicating a predominately edge-on orientation and some degree of face-on orientation, while PhF2,5 and PhF2,6 show nearly perfect edge-on orientation.

Since polymer chains are edge-on relative to the surface normal, the anisotropic properties could be investigated by collecting in-plane scattering information when films are well aligned via NGs. The measurements set-up is illustrated in the FIG. 11(j) top; the in-plane scattering information was collected in the X-ray beam directions both parallel and perpendicular to NGs. If the polymer backbone is aligned pseudo-parallel to NGs, then the interference of parallel X-rays should be enhanced, which shows a strong signal at the in-plane direction, corresponding to the π-π stacking peak intensity. Conversely, the perpendicular orientation of X-rays is less likely to be scattered by the t-plane. FIGS. 11(b), 11(e), 11(h) display the scattering images of PhF2,3, PhF2,5 and PhF2,6 films with X-ray parallel to the NGs, respectively. FIGS. 11(c), 11(f), 11(i) display the scattering images of PhF2,3, PhF2,5 and PhF2,6 films with X-ray perpendicular to the NGs, respectively. Interestingly, for PhF2,6 and PhF2,5 films, π-π stacking peaks (q_{xy}=1.75 Å⁻¹) from the perpendicular X-ray (FIGS. 11(f) and 11(i)) almost disappear while peaks from parallel X-ray (FIGS. 11(e) and 11(h)) are enhanced relative to that without NGs (also see FIGS. 12(d) and 12(f)). These anisotropic features indicate that both PhF2,5 and PhF2,6 could be well aligned, which is consistent with their device mobilities improvement in Table 5. For PhF2,3 film, the π-π stacking peak (q_{xy}=1.75 Å⁻¹) from parallel X-rays is significantly stronger than that from perpendicular X-rays or without NGs (FIG. 11(b) vs 11(c)/11(a), also see FIG. 12(b). However, the high intensity of the π-π stacking peak in FIG. 11c suggests that there is a substantially lower degree of anisotropic feature in aligned PhF2,3 film relative to that in PhF2,5 and PhF2,6 films. It could be concluded that the PhF2,3 molecule is less aligned as compared to the PhF2,5 and PhF2,6 molecules during the same processing. PhF2,3 appears less aligned and displays non-perfect edge-on orientation, which could play negative roles on charge transport capabilities, and then explain why there are more low p devices for PhF2,3 OFETs (FIG. 10b). This phenomenon is also consistent with the hypothesis that the PhF2,3 molecule shape is not as desirable as the PhF2,5 and PhF2,6 shapes for forming a well-aligned film.

Nevertheless, GIWAXS could not quantify the difference in alignment between PhF2,5 and PhF2,6 films as the X-ray could only investigate crystallized phases, not the entire film. Crystallite coherence length (CCL) was calculated along the π-π stacking direction of the parallel device films, which show a similar value of ˜6.2 nm. For aligned PhF2,5 and PhF2,6 films, there might be some difference in charge transport along intra-chain or in the amorphous region. Recently there have been publications discussing the ideal morphology for charge transport in polymer semiconductor films,^{38e,39} but there is no straightforward method for quantifying the morphology difference in the amorphous region. In addition, though best attempts were made to synthesize similar molecular weight values to minimize the molecular weight influence, the Mₙ of PhF2,6 (33 kDa) is a bit larger than that of PhF2,5 (28 kDa), and such difference might need to be considered when explaining why PhF2,6 shows a better performance.⁴⁰

Thus, the present disclosure reports on the surprising differences in chemical structure between various polymers and how these differences influence p in NG-assisted alignment. The studies presented herein show that the different difluoro substitutions affect the self-assembling behavior as the F . . . H weak interaction has been found to surprisingly and unexpectedly dominate the adjacent building blocks' conformations. Regular device characterizations indicate that the chemical structure influence on OFET devices is negligible. However, devices using NG substrates show significantly and unexpectedly improved p and the chemistry impact is clearer. The linear-shaped polymers PhF2,6 and PhF2,5 could gain a larger improvement in p due to their greater ability to adopt the shape NGs as compared to the curved polymer PhF2,3. Polymer PhF2,6 achieved the highest p of 3.9 cm²V⁻¹s⁻¹. The above results reveal that the surprising importance of chemical design on the p and suggest that a linear shape polymer might be preferred for NG-assisted alignment OFET applications.

### 8. Detailed Synthesis Steps for Schemes 1, 2, 3, and 4

Purchased Materials:

2,3-Difluoro-1,4-diiodobenzene, 1,4-Benzenediboronic acid bis(pinacol) ester, 4-bromo-3-fluoroiodobenzene and 1,4-dibromo-2,5-difluorobenzene were purchased from Sigma-Aldrich Co. 1,4-Dibromo-2,5-difluorobenzene was purified via flash column using silica gel and chloroform and hexane mixture as the eluent. Pd(PPh₃)₄ was purchased from Strem Co. DMF, Anhydrous toluene and o-xylene was purchased from Acros Co. Et₄NOH aqueous solution (20%) was purchased from TCI Chemical Co.

### Synthesis of 2,6-Di(1-bromo-2-fluoro-4-phenyl)-(4,4-dihexadecyl-4H-cyclopenta[1,2-b:5,4-b′]dithiophene (2)

In a dry 2-5 mL microwave reaction vial, (4,4-dihexadecyl-4H-cyclopenta[1,2-b: 5,4-b′]dithiophene-2,6-diyl)bis(trimethylstannane) (1) (950 mg, 1.0 mmol), 4-bromo-3-fluoroiodobenzene (650 mg, 2.2 mmol), Pd(PPh₃)₄ (34 mg, 0.03 mmol), and anhydrous toluene (5 mL) were added inside a nitrogen atmosphere glovebox. The vial was subjected to the following reaction conditions in the microwave reactor: 80° C. for 2 minutes (min), 120° C. for 2 min, and 160° C. for 60 min. The reaction was allowed to cool to room temperature, and the toluene was evaporated under vacuum via rotary evaporator. The crude mixture was purified by a silica-gel column chromatograph using hexane as the eluent to yield a yellow solid (510 mg, yield 52%).

MS(FD+): calculated 970.36, found 970.33.

¹H NMR (500 Hz, CDCl₃, ppm) δ 7.52 (t, 2H); δ 7.35 (d, 2H); δ 7.26 (d, 2H); δ 7.20 (s, 2H); δ 1.88 (m, 4H); δ 1.19 (m, 52H), δ 1.02 (m, 4H); δ 0.88 (t, 6H).

¹³C NMR (125 Hz, CDCl₃, ppm) δ 161.24, 159.28, 141.78, 137.22, 136.36, 119.21, 108.45, 108.25, 95.66, 54.45, 37.69, 31.91, 29.92, 29.68, 29.67, 29.66, 29.64, 29.58, 29.34, 29.33, 24.56, 22.68, 14.10.

### Synthesis of PF0

In a dry 2-5 mL microwave reaction vial, 2,6-dibromo-4,4-dihexadecyl-4H-cyclopenta[1,2-b:5,4-b′]dithiophene (235 mg, 0.30 mmol), 1,4-benzenediboronic acid bis(pinacol) ester (104 mg, 0.32 mmol), Pd(PPh₃)₄ (17 mg, 0.015 mmol, 0.05 eq), and dry toluene (3 mL) were added inside the nitrogen atmosphere glovebox. The vial was then sealed using a Teflon®cap and moved out of the glovebox. Then, a degassed Et₄NOH aqueous solution (20%, 1.5 mL) was injected into the vial via a syringe. The reaction mixture was stirred at 110° C. in an oil bath for 72 hours. Then, the vial was lifted up and cooled to room temperature. A mixture of Pd(PPh₃)₄ (5 mg), 2-bromothiophen (0.1 mL) in toluene (1 mL) was added via a syringe, and the reaction was kept in the oil bath again for additional 8 hours for end-capping. The reaction was allowed to cool to room temperature and the polymer was precipitated in methanol. The precipitates were collected by filter paper and washed with water and methanol respectively. Then, the polymer was extracted with methanol, hexane, and dichloromethane respectively via a Soxhlet extractor. The dichloromethane extraction was concentrated under vacuum and passed through a short silica-gel (60-100 mesh) column. Then, the polymer solution was concentrated again and added dropwise to methanol under stirring. The polymer was precipitated and collected via filter paper, and dried over in the vacuum to provide a red solid (150 mg, yield 71%. Mₙ=23 kDa, PDI=2.3).

¹H NMR (500 Hz, C₂D₂Cl₄, 100° C., ppm) δ 7.67 (s, 4H); 7.27 (s, 2H); 1.99 (b, 4H); 1.1-1.6 (m, 56H); 0.95 (t, 6H).

### Synthesis of PhF1

In a dry 2-5 mL microwave reaction vial, monomer 1 (200 mg, 0.21 mmol), monomer 2 (194 mg, 0.20 mmol), Pd(PPh₃)₄ (11 mg, 0.01 mmol), anhydrous o-xylene (2 mL), and DMF (0.4 mL) were added inside the nitrogen atmosphere glovebox. The vial was then sealed using a Teflon®cap and subjected to the following reaction conditions in the microwave reactor: 100° C. for 2 min, 150° C. for 2 min, 180° C. for 2 min, and 200° C. for 40 min. The reaction was allowed to cool to room temperature, and then the vial was transferred to the glovebox. The vial was opened to add Pd(PPh₃)₄ (3 mg), 2-bromothiophene (0.1 mL) and xylene (2 mL) for the end-capping reaction. Then, the vial was sealed again and subjected to heating in the microwave reactor under the conditions of 100° C. for 2 min, 140° C. for 2 min, and 160° C. for 20 min. The reaction was allowed to cool to room temperature and the polymer was precipitated in methanol. The precipitates were collected by filter paper and extracted with methanol, hexane, and dichloromethane respectively via a Soxhlet extractor. The dichloromethane solution was concentrated under vacuum. Then, concentrated polymer solution was passed through a short silica-gel (60-100 mesh) column. Then, it was concentrated again and was added dropwise to the methanol under stirring. The polymer was precipitated and collected via filter paper, dried over in the vacuum to provide a red solid (250 mg, yield 87%. Mₙ=25 kDa, PDI=2.4).

¹H NMR (500 Hz, C₂D₂Cl₄, 100° C., ppm) δ 7.70 (m, 2H); 7.35-7.55 (m, 6H); 7.29 (s, 2H); 1.99 (b, 8H); 1.1-1.6 (m, 112H); 0.95 (t, 12H).

### Synthesis of PhF2,5

In a dry 2-5 mL microwave reaction vial, monomer 1 (200 mg, 0.21 mmol), 1,4-dibromo-2,5-difluorobenzene (55 mg, 0.20 mmol), Pd(PPh₃)₄ (11 mg, 0.01 mmol), anhydrous o-xylene (2 mL), and DMF (0.3 mL) were added inside the nitrogen atmosphere glovebox. The vial was then sealed using a Teflon®cap and inserted into the microwave reactor. The microwave-assisted polymerization and end-capping procedures are similar to those used for the synthesis of PhF1. The reaction was allowed to cool to room temperature and the polymer was precipitated in methanol. The precipitates were collected by filter paper and extracted with methanol, hexane, dichloromethane and chloroform respectively via a Soxhlet extractor. The chloroform solution was concentrated under vacuum. Then, concentrated polymer solution was passed through a short silica-gel (60-100 mesh) column. Then, it was concentrated again and was added dropwise to the methanol under stirring. The polymer was precipitated and collected via filter paper, to provide a dark solid (100 mg, yield 68%. Mₙ=68 kDa, PDI=2.7).

¹H NMR (500 Hz, C₂D₂Cl₄, 100° C., ppm) δ 7.45 (m, 4H); 1.99 (b, 4H); 1.1-1.6 (m, 56H); 0.94 (t, 6H).

### Synthesis of 2,6-Di(1-bromo-2,3-difluoro-4-phenyl)-(4,4-dihexadecyl-4H-cyclopenta[1,2-b:5,4-b′]dithiophene (M2)

In a dry 2-5 mL microwave reaction vial, (4,4-dihexadecyl-4H-cyclopenta[1,2-b:5,4-b′]dithiophene-2,6-diyl)bis(trimethylstannane) (1) (950 mg, 1.0 mmol), 4-bromo-2,3-difluoroiodobenzene (700 mg, 2.2 mmol), Pd(PPh₃)₄ (34 mg, 0.03 mmol), and anhydrous toluene (5 mL) were added inside a nitrogen atmosphere glovebox. The vial was subjected to the following reaction conditions in the microwave reactor: 80° C. for 2 min, 120° C. for 2 min, and 160° C. for 60 min. The reaction was allowed to cool to room temperature, and the toluene was evaporated under vacuum via rotary evaporator. The crude mixture was purified by a silica-gel column chromatograph using hexane as the eluent to yield a yellow solid, 550 mg, yield 55%.

MS(FD+): calculated 1008.34, found 1008.35.

¹H NMR (500 Hz, CDCl₃, ppm) δ 7.37 (s, 2H); δ 7.30 (m, 4H); δ 1.88 (m, 4H); δ 1.10-1.30 (m, 52H), δ 0.99 (m, 4H); δ 0.87 (t, 6H)

¹³C NMR (125 Hz, CDCl₃, ppm) δ 159.33, 146.45, 137.65, 135.90, 127.81, 127.77, 124.47, 122.48, 121.79, 107.68, 107.53, 54.39, 37.64, 31.91, 29.91, 29.69, 29.67, 29.66, 29.64, 29.57, 29.55, 29.35, 29.31, 24.53, 22.68, 14.11

### Synthesis of 2,6-Di(1-bromo-2,6-difluoro-4-phenyl)-(4,4-dihexadecyl-4H-cyclopenta[1,2-b:5,4-b′]dithiophene (M3)

In a dry 2-5 mL microwave reaction vial, (4,4-dihexadecyl-4H-cyclopenta[1,2-b:5,4-b′]dithiophene-2,6-diyl)bis(trimethylstannane) (1) (950 mg, 1.0 mmol), 4-bromo-3,5-difluoroiodobenzene (700 mg, 2.2 mmol), Pd(PPh₃)₄ (34 mg, 0.03 mmol), and anhydrous toluene (5 mL) were added inside a nitrogen atmosphere glovebox. The vial was subjected to the following reaction conditions in the microwave reactor: 80° C. for 2 min, 120° C. for 2 min, 160° C. for 60 min. The reaction was allowed to cool to room temperature, and the toluene was evaporated under vacuum via the rotary evaporator. The crude mixture was purified by a silica-gel column chromatograph using hexane as the eluent to yield a yellow solid, 520 mg, yield 52%.

MS(FD+): calculated 1008.34, found 1008.30.

¹H NMR (500 Hz, CDCl₃, ppm) δ 7.21 (s, 2H); δ 7.19 (d, 2H); δ 1.87 (m, 4H); δ 1.10-1.30 (m, 52H), δ 0.99 (m, 4H); δ 0.88 (t, 6H)

¹³C NMR (125 Hz, CDCl₃, ppm) δ 161.24, 159.28, 141.78, 137.22, 136.36, 119.21, 108.35, 108.25, 95.66, 54.45, 37.69, 31.91, 29.92, 29.68, 29.67, 29.66, 29.64, 29.58, 29.34, 29.33, 24.56, 22.68, 14.10

### Synthesis of Poly {(4,4-dihexadecyl-4H-cyclopenta[1,2-b:5,4-b′]dithiophene-2,6-diyl)-alt-(2,3-difluoro-1,4-phenylene)} PhF2,3

In a dry 2-5 mL microwave reaction vial, monomer 1 (200 mg, 0.21 mmol), monomer M2 (202 mg, 0.20 mmol), Pd(PPh₃)₄ (11 mg, 0.01 mmol), anhydrous o-xylene (2 mL), and DMF (0.4 mL) were added inside the nitrogen atmosphere glovebox. The vial was then sealed using a Teflon®cap and subjected to the following reaction conditions in the microwave reactor: 100° C. for 2 min, 150° C. for 2 min, 180° C. for 2 min, and 200° C. for 40 min. The reaction was allowed to cool to room temperature, and then the vial was transferred to the glovebox. The vial was opened to add Pd(PPh₃)₄ (3 mg), 2-bromothiophene (0.1 mL) and xylene (2 mL) for the end-capping reaction. Then the vial was sealed again and subjected to heating in the microwave reactor under the conditions of 100° C. for 2 min, 140° C. for 2 min, and 160° C. for 20 min. The reaction was allowed to cool to room temperature and the polymer was precipitated in methanol. The precipitates were collected by filter paper and extracted with methanol, hexane, dichloromethane, and chloroform respectively via a Soxhlet extractor. The chloroform solution was concentrated under vacuum. Then concentrated polymer solution was passed through a short silica-gel (60-100 mesh) column. Then it was concentrated again and was added dropwise to the methanol under stirring. The polymer was precipitated and collected via filter paper, and dried over in the vacuum to provide a dark solid 260 mg, yield 88%. Mₙ=118 kDa, PDI=3.2.

### Synthesis of Poly {(4,4-dihexadecyl-4H-cyclopenta[1,2-b: 5,4-b′]dithiophene-2-yl-6-(2,6-difluorophenylene-4-yl))-alt-(4,4-dihexadecyl-4H-cyclopenta[1,2-b:5,4-b′]dithiophene-2-yl-6-(3,5-difluorophenylene-4-yl))}PhF2,6

In a dry 2-5 mL microwave reaction vial, monomer M1 (200 mg, 0.21 mmol), monomer M3 (202 mg, 0.20 mmol), Pd(PPh₃)₄ (11 mg, 0.01 mmol), anhydrous o-xylene (2 mL), and DMF (0.4 mL) were added inside the nitrogen atmosphere glovebox. The vial was then sealed using a Teflon®cap and subjected to the microwave reactor. The microwave-assist polymerization, end-capping and Soxhlet purification procedures were similar to those used for the synthesis of PhF2,3, and finally provided a dark solid 250 mg, yield 84%. Mₙ=98 kDa, PDI=3.0

### Synthesis of Poly {(4,4-dihexadecyl-4H-cyclopenta[1,2-b:5,4-b′]dithiophene-4,7-diyl))-alt-(2,5-difluoro-1,4-phenylene)} (PhF2,5)

In a dry 2-5 mL microwave reaction vial, monomer M1 (390 mg, 0.41 mmol), 1,4-dibromo-2,5-difluorobenzene (109 mg, 0.40 mmol), Pd(PPh₃)₄ (23 mg, 0.02 mmol), anhydrous o-xylene (2 mL), and DMF (0.4 mL) were added inside the nitrogen atmosphere glovebox. The vial was then sealed using a Teflon®cap and subjected to the microwave reactor. The microwave-assist polymerization, end-capping and Soxhlet purification procedures were similar to the synthesis of PhF2,5, finally provided dark solid 260 mg, yield 88%. Molecular weight in chloroform at r.t.: Mₙ=106 kDa, PDI=3.2. Molecular weight in TCB at 150° C.: Mₙ=28 kDa, PDI=2.1. ¹H NMR (500 Hz, CDCl₃, ppm) δ 7.45 (b, 4H) δ 0.60-2.10 (m, 66H).

### Synthesis of Ph4F

In a dry 2-5 mL microwave reaction vial, Monomer 1 (200 mg, 0.21 mmol), 1,4-dibromotetrafluorobenzene (62 mg, 0.20 mmol), Pd(PPh₃)₄ (11 mg, 0.01 mmol), anhydrous o-xylene (2 mL) and DMF (0.4 mL) were added inside the nitrogen atmosphere glovebox. The vial was then sealed using a Teflon®cap and inserted into the microwave reactor. The microwave-assist polymerization, end-capping, and Soxhlet purification procedures were similar to those used for the synthesis of Ph4F, and finally provided a dark solid 130 mg, yield 76%. M=57 kDa, PDI=2.9.

### Synthesis of (4,4-dimethyl-4H-cyclopenta[2,1-b:3,4-b′]dithiophen-2-yl)trimethylstannane (C1)

A solution of 4,4-dimethyl-4H-cyclopenta[2,1-b:3,4-b′]dithiophene (0.39 g, 1.9 mmol) in THF (20 ml) was cooled to −78° C. in an acetone/dry ice bath. n-Butyllithium in n-hexane (1.6 M, 1.3 mL) was added slowly. After 2 hr, a solution of trimethyltin chloride in THF (1 M, 2.6 mL) was added in one portion at −78° C., and the mixture was allowed to warm up to room temperature and stirred for another 6 h. Then the mixture was poured into water and the product was extracted with hexane three times. The organic layers were dried over sodium sulfate. The solvent was removed via a rotavapor. The crude product was used in subsequent reactions without further purification (Yield, 91%). ¹H NMR (CDCl₃, 500 MHz) δ (ppm): 7.13 (d, 1H), 7.04 (s, 1H), 6.98 (d, 1H), 1.46 (s, 6H), 0.39 (s, 9H). MS (FD+): calculated 522.04, found 522.03.

### Synthesis of 2,2′-(2,3-difluoro-1,4-phenylene)bis(4,4-dimethyl-4H-cyclopenta[2,1-b:3,4-b′]dithiophene) (CF2,3)

In a N₂ filled glovebox, a 5 mL glass tube was charged with C1 (0.17 g, 0.46 mmol), 2,3-difluoro-1,4-diiodobenzene (0.055 g, 0.15 mmol), Pd(PPh₃)₄ (6 mg), and chlorobenzene (1 mL), and sealed with a Teflon® cap. Subsequently, the reaction mixture was heated to 160° C. for 1 hr using the microwave reactor. Upon cooling, the crude product was purified with column chromatography, and then the final product was obtained as yellow solid (0.067 g, 85%). ¹H NMR (CDCl₃, 500 MHz) δ (ppm): 7.47 (s, 1H), 7.39-7.36 (m, 1H), 7.23 (d, 1H), 7.03 (d, 1H), 1.52 (s, 12H).

¹³C NMR (CDCl₃, 125 MHz) δ (ppm): 161.6, 161.4, 149.2, 149.0, 147.1, 147.0, 136.9, 136.3, 135.5, 126.4, 123.1, 123.0, 122.2, 122.1, 121.2, 121.0, 45.6, 25.5. MS (FD+): calculated 522.04, found 522.02.

### Synthesis of 2,2′-(2,5-difluoro-1,4-phenylene)bis(4,4-dimethyl-4H-cyclopenta[2,1-b:3,4-b′]dithiophene) (CF2,5)

The synthesis procedure is similar to CF2,3 and the final product was obtained as yellow solid (0.057 g, 78%). ¹H NMR (CDCl₃, 500 MHz) δ (ppm): 7.44 (s, 1H), 7.42-7.37 (m, 1H), 7.23 (d, 1H), 7.02 (d, 1H), 1.51 (s, 12H). ¹³C NMR (CDCl₃, 125 MHz) δ (ppm): 161.5, 156.0, 154.1, 154.0, 137.1, 136.1, 135.5, 126.5, 122.4, 122.3, 122.2, 121.2, 120.9, 114.6, 114.5, 114.4, 45.6, 25.5.

MS (FD+): calculated 522.04, found 522.03.

### Synthesis of 2,2′-(2,6-difluoro-1,4-phenylene)bis(4,4-dimethyl-4H-cyclopenta[2,1-b:3,4-b′]dithiophene) (CF2,6)

The synthesis procedure is similar to CF2,3 and the final product was obtained as yellow solid (0.047 g, 82%). ¹H NMR (CDCl₃, 500 MHz) δ (ppm): 7.55 (s, 1H), 7.29 (s, 1H), 7.25-7.20 (m, 4H), 7.21 (s, 1H), 7.04-7.01 (m, 2H), 1.52 (s, 6H), 1.50 (s, 6H). ¹³C NMR (CDCl₃, 125 MHz) δ (ppm): 161.7, 161.5, 161.3, 160.9, 160.8, 160.6, 158.9, 158.8, 141.7, 137.8, 136.7, 135.6, 135.4, 134.7, 129.9, 126.5, 126.3, 123.1, 123.0, 121.2, 118.6, 111.5, 108.6, 108.4, 45.7, 45.5, 25.5. MS (FD+): calculated 522.04, found 521.99.

Process Steps

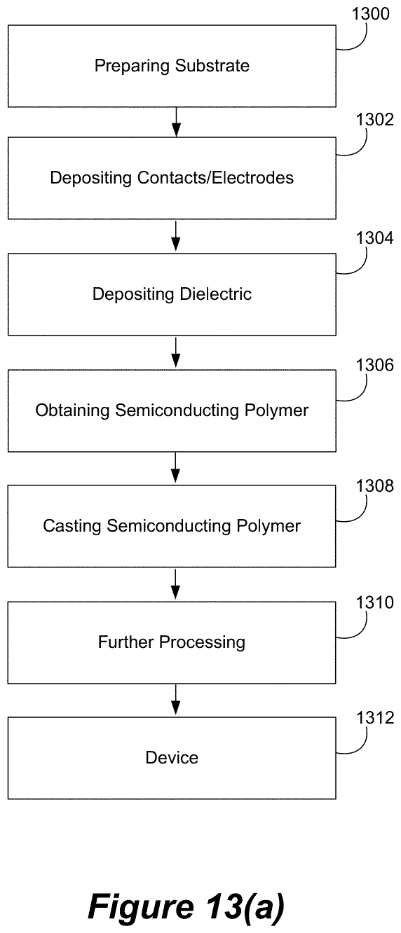

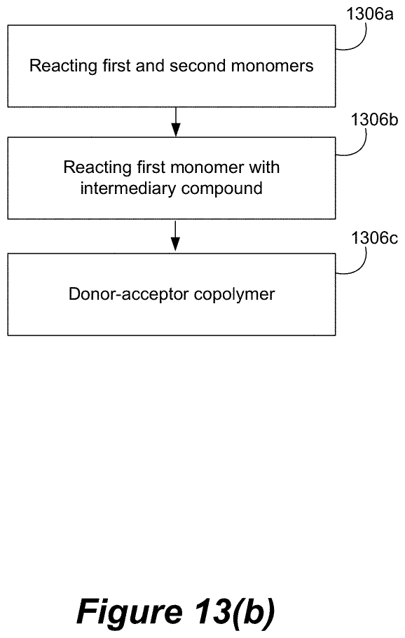

FIG. 13(a) is a flowchart illustrating a method for fabricating a film or device such as an OFET. The method can comprise the following steps.

Block 1300 represents obtaining/providing and/or preparing a substrate. In one or more embodiments, the substrate comprises a flexible substrate. Examples of a flexible substrate include, but are not limited to, a plastic substrate, a polymer substrate, a metal substrate, or a glass substrate. In one or more embodiments, the flexible substrate is at least one film or foil selected from a polyimide film, a polyether ether ketone (PEEK) film, a polyethylene terephthalate (PET) film, a polyethylene naphthalate (PEN) film, a polytetrafluoroethylene (PTFE) film, a polyester film, a metal foil, a flexible glass film, and a hybrid glass film. In one or more embodiments, the substrate is a swellable substrate.

Block 1302 represents optionally forming/depositing contacts or electrodes (e.g., p-type, n-type contacts, a gate, a source, and/or drain contacts) on or above (or as part of) the substrate.

In an OFET embodiment comprising a top gate & bottom contact geometry, source and drain contacts are deposited on the substrate. Examples of materials for the source and drain contacts include, but are not limited to, gold, silver, silver oxide, nickel, nickel oxide (NiOx), molybdenum, and/or molybdenum oxide. In one or more embodiments, the source and drain contacts of the OFET further comprise a metal oxide electron blocking layer, wherein the metal in the metal oxide includes, but is not limited to, nickel, silver, or molybdenum.

In an OFET embodiment comprising a bottom gate geometry, a gate electrode is deposited on the substrate. In one or more embodiments, the gate contact (gate electrode) is a thin metal layer. Examples of the metal layer for the gate include, but are not limited to, an aluminum layer, a copper layer, a silver layer, a silver paste layer, a gold layer or a Ni/Au bilayer. Examples of the gate contact further include, but are not limited to, a thin Indium Tin Oxide (ITO) layer, a thin fluorine doped tin oxide (FTO) layer, a thin graphene layer, a thin graphite layer, or a thin PEDOT:PSS layer. In one or more embodiments, the thickness of the gate electrode is adjusted (e.g., made sufficiently thin) depending on the flexibility requirement.

The gate, source, and drain contacts can be printed, thermally evaporated, or sputtered, for example.

Block 1304 represents optionally depositing a dielectric on the gate electrode, e.g., when fabricating an OFET in a bottom gate configuration. In this example, the dielectric is deposited on the gate contact's surface to form a gate dielectric.

Examples of depositing the dielectric include forming a coating including one or one or more dielectric layers on the substrate (and selecting a thickness of the dielectric layers or coating). In one or more examples, the dielectric is structured or patterned, e.g., to form nanogrooves or nanostructures in the dielectric. Examples of dimensions for the nanogrooves include, but are not limited to, a nanogroove depth of 6 nanometers or less and/or a nanogroove width of 100 nm or less.

Examples of dielectric layers include, but are not limited to, a single polymer (e.g., PVP) dielectric layer or multiple dielectric layers (e.g., bilayer dielectric). A single polymer dielectric layer may be preferred in some embodiments (for easier processing, or for more flexibility). In one embodiment, the dielectric layer comprises silicon dioxide (SiO₂). In another embodiment, the dielectric layers form a polymer/SiO₂ bilayer. In yet another embodiment, the dielectric layers form a polymer dielectric/SiO₂/SAM multilayer with the SiO₂ on the polymer and the alkylsilane or arylsilane Self Assembled Monolayer (SAM) layer on SiO₂. In yet a further embodiment, the dielectric layers form a SiO₂/SAM bilayer with the alkylsilane or arylsilane SAM layer on the SiO₂. Various functional groups may be attached to the end of the alkyl groups to modify the surface property of the SAM layer.

The thickness of the SiO₂ may be adjusted (e.g., made sufficiently thin) depending on the composition of the dielectric layers and the flexibility requirement. For example, in one embodiment, the dielectric layer might not include a polymer dielectric layer and still be flexible.

In one or more embodiments, the nanogrooves/nanostructures are formed/patterned using nano imprint lithography. In one example, patterning the dielectric layers comprises nano-imprinting a first dielectric layer (e.g., PVP) deposited on a gate metal surface of the substrate; and depositing a second dielectric layer on the nanoimprinted first dielectric layer, wherein a thickness of the second dielectric layer (e.g., comprising SiO₂) is adjusted.

Block 1306 represents fabricating/obtaining one or more conjugated donor-acceptor semiconducting copolymers comprising a main chain section, the main chain section having a repeat unit that comprises at least one donor (e.g., such as CDT or a CDT-type) and at least one acceptor, wherein the at least one acceptor comprises a fluorophenylene. Examples of the fluorophenylene as the acceptor include fluorphenylene units having the structural formula:

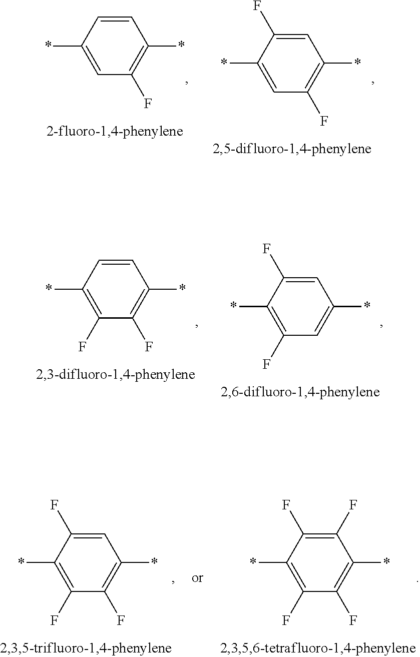

The 2-fluoro-1,4-phenylene, 2,6-difluoro-1,4-phenylene, and 2,3,5-trifluoro-1,4-phenylene may form regioregular polymers, whereas the other fluorophenylenes (2,5-difluoro-1,4-phenylene, 2,3-difluoro-1,4-phenylene, and 2,3,5,6-tetrafluoro-1,4-phenylene) do not. Any donor can be used in the co-polymers, including those described in the references section below. Examples of the donor in the repeat unit include dithiophenes having the structure:

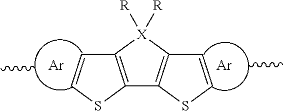

wherein each Ar is independently a substituted or non-substituted aromatic functional group (or each Ar is independently nothing and the valence of its respective thiophene ring is completed with hydrogen), each R is independently hydrogen or a substituted or non-substituted alkyl, aryl, or alkoxy chain, and X is C, Si, Ge, N or P. The R groups can be the same or different. In the dithiophene, the R comprising the substituted or non-substituted alkyl, aryl or alkoxy chain can be a C₆-C₃₀ substituted or non-substituted alkyl or alkoxy chain, —(CH₂CH₂O)n (n=2˜20), C₆H₅, —CₙF₍₂ₙ₊₁₎ (n=2˜20), —(CH₂)ₙN(CH₃)₃Br (n=2˜20), 2-ethylhexyl, PhCmH₂ₘ₊₁ (m=1˜20), —(CH₂)ₙN(C₂H₅)₂ (n=2˜20), —(CH₂)ₙSi(CmH₂ₘ₊₁)₃ (m, n=1 to 20), or —(CH₂)ₙSi(OSi(CmH₂ₘ₊₁)₃)ₓ(CpH₂ₚ₊₁)_{y} (m, n, p=1 to 20, x+y=3). Examples of dithiophene units include those illustrated in Table B (FIG. 30B) in U.S. Utility patent application Ser. No. 14/426,467, filed on Mar. 6, 2015, by Hsing-Rong Tseng, Lei Ying, Ben B. Y. Hsu, Christopher J. Takacs, and Guillermo C. Bazan, entitled “FIELD-EFFECT TRANSISTORS BASED ON MACROSCOPICALLY ORIENTED POLYMERS,” Attorney's Docket No. 30794.0514-US-WO (UC REF 2013-030).

For example, the dithiophene unit could comprise:

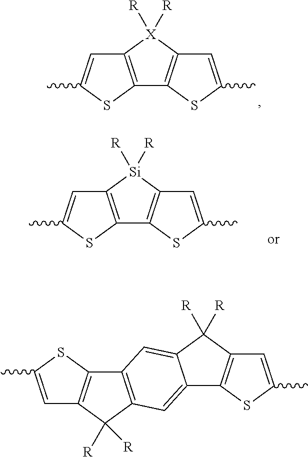

In one or more embodiments, the semiconducting polymer has the repeating unit structure [D-A]ₙ or [D-A-D-A]ₙ wherein D comprises the donor, A comprises the acceptor, and n is an integer representing the number of repeating units. In one or more embodiments, the structure has a regioregular conjugated main chain section having n=5-150, or more, contiguous repeat units. In some embodiments, the number of repeat units n is in the range of 10-40 repeats. The regioregularity of the conjugated main chain section can be 95% or greater, for example.

Examples of the regioregular semiconducting polymer comprise a repeating unit of the structure:

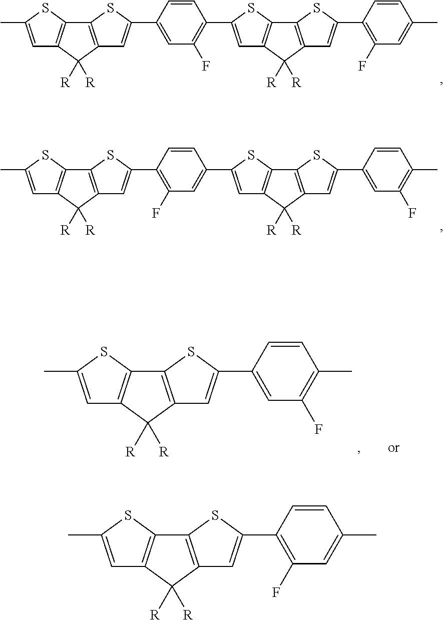

where the phenylene comprising F is regioregularly arranged along the conjugated main chain section (e.g., pointing toward the direction shown in the structures above), the R groups comprise H or a substituted or non-substituted alkyl, aryl or alkoxy chain comprising, for example, a C₆-C₃₀ substituted or non-substituted alkyl or alkoxy chain, —(CH₂CH₂O)n (n=2˜20), C₆H₅, —CₙF(2n+1) (n=2˜20), —(CH₂)ₙN(CH₃)₃Br (n=2˜20), 2-ethylhexyl, PhCmH₂ₘ₊₁ (m=1-20), —(CH₂)ₙN(C₂H₅)₂ (n=2˜20), —(CH₂)ₙSi(CmH₂ₘ₊₁)₃ (m, n=1 to 20), or —(CH₂)ₙSi(OSi(CmH₂ₘ₊₁)₃)ₓ(CₚH₂ₚ₊₁)_{y} (m, n, p=1 to 20, x+y=3).

Other examples of regioregular structures include those described above but with the 2-fluoro-1,4-phenylene replaced with 2,6-difluoro-1,4-phenylene or 2,3,5-trifluoro-1,4-phenylene.

Further example regioregular structures include:

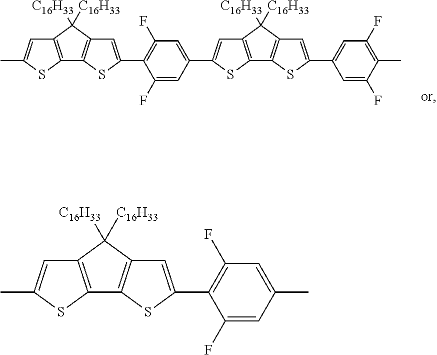

Examples of non-regioregular structures include:

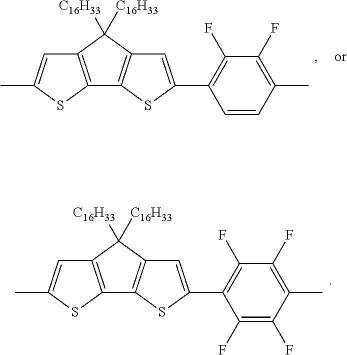

In the above examples, the C₁₆H₃₃ can be other R as described above.

FIG. 13(b) illustrates a method of fabricating the copolymer comprising the following steps. Block 1306a represents reacting a first monomer, comprising a donor (e.g., dithiophene) and at least one organostannane (e.g., compound 1 in Schemes 1 or 2), with a second monomer. In one embodiment, the second monomer comprises benzene substituted with iodine, bromine, and fluorine (e.g., 4-bromo-3-fluoroiodobenzene), and the reacting is under conditions to form an intermediary compound (e.g., compound 2 in Scheme 1). Block 1306b represents reacting the first monomer with the intermediary compound to form a regioregular donor-acceptor copolymer (e.g., PhF1), as represented by Block 1306c. In another embodiment, the reacting of Block 1306a comprises reacting the first monomer (e.g., compound 1 in Schemes 1 or 2) with one or more fluorinated phenyl units (e.g., 1,4-dibromo-2,5-difluo-benzene) to form the donor-acceptor copolymer (e.g., PhF2,5) represented by Block 1306c. Note that the C₁₆H₃₃ in compound 1 (or other compounds in Schemes 1 or 2) can be replaced with R units as discussed above, to form different copolymers.

Block 1308 represents solution casting/processing a solution comprising the semiconducting copolymer(s) (e.g., onto the dielectric) to form a film comprising the semiconducting copolymer(s).

Solution casting methods include, but are not limited to, inkjet printing, bar coating, spin coating, blade coating, spray coating, roll coating, dip coating, free span coating, dye coating, screen printing, and drop casting.

The nanogrooves can provide nucleation sites for growth of the polymer chains within the solution so that one or more of the polymer chains seed and stack within one or more of the nanogrooves.

Block 1310 represents further processing the polymer film cast on the patterned dielectric layers. The step can comprise annealing/curing the film or allowing the film to dry. The step can comprise depositing source and drain contacts as described above, if necessary.

Block 1312 represents the end result, a device or film useful in a device.

In one or more film embodiments, the film comprises the donor-acceptor copolymer polymer chains stacked into one or more fibers. For example, one or more of the structures (e.g., nanogrooves) in the dielectric or substrate on which the film is deposited can contact and align/orient one or more of the fibers such that the fibers are continuously aligned with (and/or at least partially lie within) one or more of the structures (e.g., nanogrooves). The width of an individual fiber can be about 2-3 nm, and fibers on the nanostructured/nanogrooved substrate can form, or stack into, fiber bundles having a width of 50-100 nm (as compared to fiber bundles having a width between 30-40 nm when fabricated on a non-structured substrate). In one or more embodiments, the aligned conjugated polymer chains are stacked to form a crystalline structure, and the polymer chains are oriented with an orientational order parameter between 0.9 and 1. The main-chain axes of the polymer chains can be aligned along the long-axis of the fiber while π-π stacking of the polymer chains can be in a direction along the short-axis of the fiber.

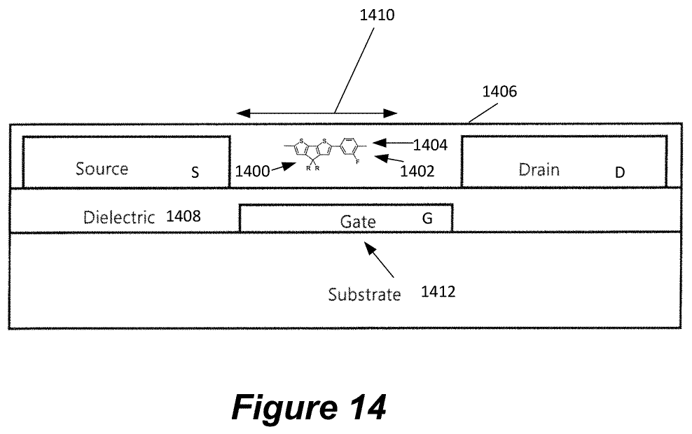

FIG. 14 illustrates an OFET comprising one or more (e.g., aligned) donor-acceptor copolymers 1400 each comprising a main chain section 1402, the main chain section 1402 having a repeat unit 1404 that comprises at least one donor D (e.g., as described in Block 1306) and at least one acceptor A, and wherein acceptor A comprises a phenylene having a structural formula described in Block 1306.

The OFET further comprises a source contact S and a drain contact D to a film 1406 comprising the semiconducting polymer 1400; and a gate connection/contact G on a dielectric 1408, wherein the gate connection G applies a field to the semiconducting polymer 1400 across the dielectric 1408 between the polymer 1400 and the gate G to modulate conduction along the semiconducting polymer 1400 in a channel between the source contact S and the drain contact D, thereby switching the OFET on or off.

In one or more embodiments, the OFET comprises means (e.g., grooves, nanogrooves or statutory equivalents thereof) for aligning the main chain axes 1410 of the polymer 1400 to the channel. The nanogrooves can orient/align the polymer chains 1402 so that polymer chains 1402 each have their backbone substantially parallel to a longitudinal axis of at least one of the nanogrooves, and the conduction between the source contact S and the drain contact D is predominantly along the backbones/main chain axes 1410 substantially parallel to a longitudinal axis of at least one of the nanogrooves, although charge hopping between adjacent polymers in a fiber bundle is also possible. For example, the means can align the main chain axes to an imaginary line bounded by the source S and the drain D or the means can align the main chain axes 1410 to an alignment direction in the channel between Source S and Drain D. The source and drain can be positioned such that a minimum distance between the source contact and drain contact is substantially parallel to the longitudinal axis of the nanogrooves.

In other embodiments, means for aligning the semiconducting polymers comprises a fabrication method, including, but not limited to, blade coating, dip coating, and bar coating (or statutory equivalents thereof) of the semiconducting polymers on dielectric 1408 or substrate 1412.

Embodiments of the present invention are not limited to the particular sequence of depositing the source, drain, and gate contacts. For example, OFETs according to one or more embodiments of the present invention can be fabricated in a bottom gate & top contact geometry, bottom gate & bottom contact geometry, top gate & bottom contact geometry, and top gate & top contact geometry²⁹.

In various embodiments, the source, drain, gate, and dielectric have one or more compositions, structures, or configurations, the donor-acceptor copolymer has a structure (including regioregularity), acceptor composition, donor composition, LUMO, stability, and is disposed in a film having a crystallinity, quality, and morphology, and the OFET and the donor-acceptor copolymers are fabricated/processed under conditions described herein, such that:
the OFET has a field effect (saturation regime) mobility of at least 0.68 cm²V⁻¹s⁻¹ or in a range of 0.5-2 cm²V⁻¹s⁻¹ (e.g., when the semiconducting polymer is cast on the dielectric that does not contain structures that align the copolymers), e.g., when the drain voltage V_{d} is greater than −60 V, e.g., V_{d} is in a range of −60 V to −120 V; and/or
the OFET has a field effect (saturation regime) mobility of at least 2.2 cm²V⁻¹s⁻¹ or in a range of 2-50 cm²V⁻¹s⁻¹ (e.g., when the semiconducting polymer is aligned by casting on the dielectric that contains nanogrooves), e.g., when the drain voltage V_{d} is greater than −60 V, e.g., V_{d} is in a range of −60 V to −120 V; and/or
the OFET has an on/off ratio of at least 10⁴, at least 10⁵, or at least 10⁶;
the OFET exhibits unipolar p-type transport characteristics; and/or
the copolymer has a bandgap of at least 1.9 eV (e.g., in a range of 1.9 eV-2.1 eV) and/or a Lowest Unoccupied Molecular Orbital (LUMO) having an energy greater than −3.5 electron volts; and/or
the donor-acceptor copolymers are stacked to form a crystalline structure, e.g., characterized by one or more peaks having a full width at half maximum of less than 0.1 Angstroms⁻¹ as measured by an out of plane grazing incidence wide angle X-ray scattering (GIWAXS) measurement of the crystalline structure; and/or
the film comprising the donor-acceptor copolymers has a surface roughness of less than 2 nanometers, or less than 1 nanometer, over a 5 micron by 5 micron area.

Thus, one or more embodiments of the present invention describe devices (e.g., an OFET) comprising a donor acceptor copolymer and means (at least one fluorophenylene unit as an acceptor) for providing the OFET with a desired mobility, desired on-off ratio, more stable on/off current, unipolar p-type transport, reduced electron injection from electrodes, desired crystallinity, and/or desired surface smoothness, as described herein.

### Advantages and Improvements

Most conjugated polymers for OFETs are usually designed in a donor-acceptor fashion, and those high mobility polymers typically use strong acceptor units in their structures. Such strong acceptor units may induce an ambipolar characteristic in the p-type OFET device operation.

The present disclosure, on the other hand, reports on the surprising and unexpected discovery that new polymers using fluorinated phenylene as the acceptor unit and incorporated into OFET devices result in the OFET devices having a combination of one or more desirable properties as described herein, including unipolar p-type characteristics and high mobilities relative to similar structures with strong acceptor units. Illustrative embodiments that have been synthesized include novel wide-gap polymers (E_{g}: 1.9˜2.1 eV) incorporating cyclopentadithiophene and phenylene units with different fluorine substitutions. The Polymer PhF2,5, for example, has two fluorine atoms on the phenyl unit and shows a planar backbone structure, excellent thermal stability and well-ordered film organizations with improvements relative to the polymers without fluorine substitution. Moreover, OFETs incorporating the PhF2,5 have an average field-effect mobility of 0.68±0.18 cm²V⁻¹s⁻¹ on a smooth substrate, which is of the same order as previously reported narrow bandgap polymers such as CDTBTZ (1.25 eV). OFET mobility of PhF2,3, PhF2,6, and Ph4F devices are 0.9 cm²V⁻¹s⁻¹, 0.7 cm²V⁻¹s⁻¹, and 0.05 cm²V⁻¹s⁻¹, respectively, on smooth substrates. OFET mobility of PhF2,3, PhF2,6, and PhF2,5 devices increase to 1.8±0.5 cm²V⁻¹s⁻¹, 3.1±0.5 cm²V⁻¹s⁻¹, and 2.2±0.3 cm²V⁻¹s⁻¹, respectively, on nano-grooved substrates.

### REFERENCES

The following references are incorporated by reference herein.
(1) (a) Wang, C. L.; Dong, H. L.; Hu, W. P.; Liu, Y. Q.; Zhu, D. B. Chem. Rev. 2012, 112, 2208. (b) Olivier, Y.; Niedzialek, D.; Lemaur, V.; Pisula, W.; Mullen, K.; Koldemir, U.; Reynolds, J. R.; Lazzaroni, R.; Cornil, J.; Beljonne, D. Adv. Mater. 2014, 26, 2119.
(2) Nielsen, C. B.; Turbiez, M.; McCulloch, I. Adv. Mater. 2013, 25, 1859.
(3) (a) Stalder, R.; Mei, J. G; Graham, K. R.; Estrada, L. A.; Reynolds, J. R. Chem. Mater. 2014, 26, 664. (b) Lei, T.; Wang, J. Y; Pei, J. Accounts Chem. Res. 2014, 47, 1117.
(4) (a) Tsao, H. N.; Cho, D. M.; Park, I.; Hansen, M. R.; Mavrinskiy, A.; Yoon, D. Y; Graf, R.; Pisula, W.; Spiess, H. W.; Mullen, K. J. Am. Chem. Soc. 2011, 133, 2605. (b) Zhang, W. M.; Smith, J.; Watkins, S. E.; Gysel, R.; McGehee, M.; Salleo, A.; Kirkpatrick, J.; Ashraf, S.; Anthopoulos, T.; Heeney, M.; McCulloch, I. J. Am. Chem. Soc. 2010, 132, 11437. (c) Tseng, H. R.; Phan, H.; Luo, C.; Wang, M.; Perez, L. A.; Patel, S. N.; Ying, L.; Kramer, E. J.; Nguyen, T. Q.; Bazan, G C.; Heeger, A. J. Adv. Mater. 2014, 26, 2993.
(5) (a) Beaujuge, P. M.; Frechet, J. M. J. J. Am. Chem. Soc. 2011, 133, 20009. (b) Biniek, L.; Schroeder, B. C.; Nielsen, C. B.; McCulloch, I. J. Mater Chem. 2012, 22, 14803. (c) Mei, J. G; Diao, Y; Appleton, A. L.; Fang, L.; Bao, Z. N. J. Am. Chem. Soc. 2013, 135, 6724.
(6) (a) Phan, H.; Wang, M.; Bazan, G C.; Nguyen, T. Q. Adv. Mater 2015, 27, 7004. (b) Ford, M. J.; Wang, M.; Phan, H.; Nguyen, T. Q.; Bazan, G C. Adv. Funct. Mater 2016, DOI: adfm.201601294.
(7) Zhao, Y; Guo, Y L.; Liu, Y Q. Adv. Mater 2013, 25, 5372.
(8) (a) McCulloch, I.; Heeney, M.; Chabinyc, M. L.; DeLongchamp, D.; Kline, R. J.; Coelle, M.; Duffy, W.; Fischer, D.; Gundlach, D.; Hamadani, B.; Hamilton, R.; Richter, L.; Salleo, A.; Shkunov, M.; Sporrowe, D.; Tierney, S.; Zhong, W. Adv. Mater 2009, 21, 1091. (b) Fei, Z. P.; Pattanasattayavong, P.; Han, Y; Schroeder, B. C.; Yan, F.; Kline, R. J.; Anthopoulos, T. D.; Heeney, M. J. Am. Chem. Soc. 2014, 136, 15154. (c) Jang, S. Y; Kim, I. B.; Kim, J.; Khim, D.; Jung, E.; Kang, B.; Lim, B.; Kim, Y A.; Jang, Y H.; Cho, K.; Kim, D. Y Chem. Mater 2014, 26, 6907. (d) Boufflet, P.; Han, Y; Fei, Z. P.; Treat, N. D.; Li, R. P.; Smilgies, D. M.; Stingelin, N.; Anthopoulos, T. D.; Heeney, M. Adv. Funct. mater. 2015, 25, 7038.
(9) Zhang, M.; Tsao, H. N.; Pisula, W.; Yang, C. D.; Mishra, A. K.; Mullen, K. J. Am. Chem. Soc. 2007, 129, 3472.
(10) (a) Ying, L.; Hsu, B. B. Y; Zhan, H. M.; Welch, G C.; Zalar, P.; Perez, L. A.; Kramer, E. J.; Nguyen, T. Q.; Heeger, A. J.; Wong, W. Y; Bazan, G C. J. Am. Chem. Soc. 2011, 133, 18538. (b) Wang, M.; Ford, M.; Phan, H; Coughlin, J.; Nguyen, T. Q.; Bazan, G C. Chem. Commun., 2016, 52, 3207.
(11) Zhou, H. X.; Yang, L. Q.; You, W. Macromolecules 2012, 45, 607.
(12) (a) Jackson, N. E.; Savoie, B. M.; Kohlstedt, K. L.; de la Cruz, M. O.; Schatz, G C.; Chen, L. X.; Ratner, M. A. J. Am. Chem. Soc. 2013, 135, 10475. (b) Chen, Z. H.; Cai, P.; Chen, J. W.; Liu, X. C.; Zhang, L. J.; Lan, L. F.; Peng, J. B.; Ma, Y G.; Cao, Y Adv. Mater 2014, 26, 2586. (c) Lei, T.; Xia, X.; Wang, J. Y; Liu, C. J.; Pei, J. J. Am. Chem. Soc. 2014, 136, 2135. (d) Coughlin, J. E.; Zhugayevych, A.; Bakus, R. C.; van der Poll, T. S.; Welch, G C.; Teat, S. J.; Bazan, G C.; Tretiak, S. J. Phys. Chem. C 2014, 118, 15610. (e) Nielsen, C. B.; White, A. J. P.; McCulloch, I. J. Org. Chem. 2015, 80, 5045. (f) Fei, Z. P.; Boufflet, P.; Wood, S.; Wade, J.; Moriarty, J.; Gann, E.; Ratcliff, E. L.; McNeill, C. R.; Sirringhaus, H.; Kim, J. S.; Heeney, M. J. Am. Chem. Soc. 2015, 137, 6866.
(13) Perez, L. A.; Zalar, P.; Ying, L.; Schmidt, K.; Toney, M. F.; Nguyen, T. Q.; Bazan, G C.; Kramer, E. J. Macromolecules 2014, 47, 1403.
(14) Brown, P. J.; Thomas, D. S.; Kohler, A.; Wilson, J. S.; Kim, J. S.; Ramsdale, C. M.; Sirringhaus, H.; Friend, R. H. Phys. Rev. B. 2003, 67, 064203.
(15) Cardona, C. M.; Li, W.; Kaifer, A. E.; Stockdale, D.; Bazan, G C. Adv. Mater 2011, 23, 2367.
(16) Ford, M. J.; Wang, M.; Patel, S. N.; Phan, H.; Segalman, R. A.; Nguyen, T. Q.; Bazan, G C. Chem. Mater 2016, DOI: 10.1021/acs.chemmater.5b04774
(17) Himmelberger, S.; Vandewal, K.; Fei, Z. P.; Heeney, M.; Salleo, A. Macromolecules 2014, 47, 7151.
(18) Li, W. T.; Yang, L. Q.; Tumbleston, J. R.; Yan, L.; Ade, H.; You, W. Adv Mater 2014, 26, 4456.
(19) Chabinyc, M. L. Polym. Rev. 2008, 48, 463.
(20) Ilavsky, J. J. Appl. Cryst. 2012, 45, 324.
(21) Hexemer, A.; Bras, W.; Glossinger, J.; Schaible, E.; Gann, E.; Kirian, R.; MacDowell, A.; Church, M.; Rude, B.; Padmore, H. J. Phys. Conf. Ser. 2010, 247, 012007.
(22) Bong-Gi Kim et. al., Nature materials Vol. 12, July 2013, entitled A molecular design principle of lyotropic liquid crystalline conjugated polymers with directed alignment capability for plastic electronics.
(23) Jung Ha Park et al., A Fluorinated Phenylene Unit as a Building Block for High-Performance n-Type Semiconducting Polymer, Adv. Mater. 2013. 25, 2583-2588.
(24) Prashant Sonar et. al., Thiophene-tetrafluorophenyl-thiophene: a promising building block for ambipolar organic field effect transistors, J. Mater. Chem. C., 2015, 3, 2080.
(25) International Patent Publication No. WO/2014/202184.
(26) International Patent Publication No. WO/2013/120590.
(27) Hole Mobility and Electron Injection Properties of D-A Conjugated Copolymers with Fluorinated Phenylene Acceptor Units,” by Ming Wang, Michael Ford, Alexander T. Lill, Hung Phan, Thuc-Quyen Nguyen, and Guillermo C. Bazan Adv. Mater. 2017, 29, 1603830.
(28) Supporting Information for (27).
(29) DiBenedetto et. al., Molecular Self-Assembled Monolayers and Multilayers for Organic and Unconventional Inorganic Thin-Film Transistor Applications, Adv. Mater. 2009, 21, 1407-1433 DOI 10.1002/adma.200803267.
(30) Yan, P.; Xie, A. F.; Wei, M. D.; Loew, L. M. J. Org. Chem. 2008, 73, 6587.
(31) Wang, M.; Ford, M. J.; Lill, A. T.; Phan, H.; Nguyen, T. Q.; Bazan, G. C. Adv. Mater. 2017, 29, 1603830.
(32) (a) Tsao, H. N.; Cho, D. M.; Park, I.; Hansen, M. R.; Mavrinskiy, A.; Yoon, D. Y.; Graf, R.; Pisula, W.; Spiess, H. W.; Miillen, K. J. Am. Chem. Soc. 2011, 133, 2605. (b) Tseng, H. R.; Phan, H.; Luo, C.; Wang, M.; Perez, L. A.; Patel, S. N.; Ying, L.; Kramer, E. J.; Nguyen, T. Q.; Bazan, G. C.; Heeger, A. J. Adv. Mater. 2014, 26, 2993. (c) Himmelberger, S.; Vandewal, K.; Fei, Z. P.; Heeney, M.; Salleo, A. Macromolecules 2014, 47, 7151.
(33) (a) Lee, W.; Kim, G. H.; Ko, S. J.; Yum, S.; Hwang, S.; Cho, S.; Shin, Y H.; Kim, J. Y; Woo, H. Y Macromolecules 2014, 47, 1604. (b) Vezie, M. S.; Few, S.; Meager, I.; Pieridou, G; Dorling, B.; Ashraf, R. S.; Goni, A. R.; Bronstein, H.; McCulloch, I.; Hayes, S. C.; Campoy-Quiles, M.; Nelson, J. Nat. Mater. 2016, 15, 746.
(34) (a) Rieger, R.; Beckmann, D.; Mavrinskiy, A.; Kastler, M.; Mullen, K. Chem. Mater. 2010, 22, 5314. (b) Osaka, I.; Abe, T.; Shinamura, S.; Takimiya, K. J. Am. Chem. Soc. 2011, 133, 6852. (c) Lei, T.; Cao, Y; Zhou, X.; Peng, Y; Bian, J.; Pei, J. Chem. Mater. 2012, 24, 1762. (d) Lei, T.; Wang, J. Y; Pei, J. Accounts Chem. Res. 2014, 47, 1117.
(35) (a) Lei, T.; Xia, X.; Wang, J. Y; Liu, C. J.; Pei, J. J. Am. Chem. Soc. 2014, 136, 2135. (b) Li, W. T.; Abrecht, S.; Yang, L. Q.; Roland, S.; Tumbleston, J. R.; McAfee, T.; Yan, L.; Kelly, M. A.; Ade, H.; Neher, D.; You, W. J. Am. Chem. Soc. 2014, 136, 15566.
(36) (a) McCulloch, I.; Heeney, M.; Chabinyc, M. L.; DeLongchamp, D.; Kline, R. J.; Coelle, M.; Duffy, W.; Fischer, D.; Gundlach, D.; Hamadani, B.; Hamilton, R.; Richter, L.; Salleo, A.; Shkunov, M.; Sporrowe, D.; Tierney, S.; Zhong, W. Adv. Mater. 2009, 21, 1091. (b) Fei, Z. P.; Pattanasattayavong, P.; Han, Y; Schroeder, B. C.; Yan, F.; Kline, R. J.; Anthopoulos, T. D.; Heeney, M. J. Am. Chem. Soc. 2014, 136, 15154. (c) Jang, S. Y; Kim, I. B.; Kim, J.; Khim, D.; Jung, E.; Kang, B.; Lim, B.; Kim, Y A.; Jang, Y H.; Cho, K.; Kim, D. Y Chem. Mater. 2014, 26, 6907. (d) Boufflet, P.; Han, Y; Fei, Z. P.; Treat, N. D.; Li, R. P.; Smilgies, D. M.; Stingelin, N.; Anthopoulos, T. D.; Heeney, M. Adv. Funct. Mater. 2015, 25, 7038. (e) Son, S. Y; Kim, Y; Lee, J.; Lee, G Y; Park, W. T.; Noh, Y Y; Park, C. E.; Park, T. J. Am. Chem. Soc. 2016, 138, 8096.
(37) (a) Tsao, H. N.; Cho, D. M.; Park, I.; Hansen, M. R.; Mavrinskiy, A.; Yoon, D. Y; Graf, R.; Pisula, W.; Spiess, H. W.; Müllen, K. J. Am. Chem. Soc. 2011, 133, 2605. (b) Tseng, H. R.; Phan, H.; Luo, C.; Wang, M.; Perez, L. A.; Patel, S. N.; Ying, L.; Kramer, E. J.; Nguyen, T. Q.; Bazan, G C.; Heeger, A. J. Adv. Mater. 2014, 26, 2993. (c) Himmelberger, S.; Vandewal, K.; Fei, Z. P.; Heeney, M.; Salleo, A. Macromolecules 2014, 47, 7151.
(38) (a) McCulloch, I.; Heeney, M.; Chabinyc, M. L.; DeLongchamp, D.; Kline, R. J.; Coelle, M.; Duffy, W.; Fischer, D.; Gundlach, D.; Hamadani, B.; Hamilton, R.; Richter, L.; Salleo, A.; Shkunov, M.; Sporrowe, D.; Tierney, S.; Zhong, W. Adv. Mater. 2009, 21, 1091. (b) Fei, Z. P.; Pattanasattayavong, P.; Han, Y; Schroeder, B. C.; Yan, F.; Kline, R. J.; Anthopoulos, T. D.; Heeney, M. J. Am. Chem. Soc. 2014, 136, 15154. (c) Jang, S. Y; Kim, I. B.; Kim, J.; Khim, D.; Jung, E.; Kang, B.; Lim, B.; Kim, Y A.; Jang, Y H.; Cho, K.; Kim, D. Y Chem. Mater. 2014, 26, 6907. (d) Boufflet, P.; Han, Y; Fei, Z. P.; Treat, N. D.; Li, R. P.; Smilgies, D. M.; Stingelin, N.; Anthopoulos, T. D.; Heeney, M. Adv. Funct. Mater. 2015, 25, 7038. (e) Son, S. Y; Kim, Y; Lee, J.; Lee, G Y; Park, W. T.; Noh, Y Y; Park, C. E.; Park, T. J. Am. Chem. Soc. 2016, 138, 8096.
(39) Noriega, R.; Rivnay, J.; Vandewal, K.; Koch, F. P. V.; Stingelin, N.; Smith, P.; Toney, M. F.; Salleo, A. Nat. Mater. 2013, 12, 1037.
(40) (a) Tsao, H. N.; Cho, D. M.; Park, I.; Hansen, M. R.; Mavrinskiy, A.; Yoon, D. Y; Graf, R.; Pisula, W.; Spiess, H. W.; Miillen, K. J. Am. Chem. Soc. 2011, 133, 2605. (b) Tseng, H. R.; Phan, H.; Luo, C.; Wang, M.; Perez, L. A.; Patel, S. N.; Ying, L.; Kramer, E. J.; Nguyen, T. Q.; Bazan, G C.; Heeger, A. J. Adv. Mater. 2014, 26, 2993. (c) Himmelberger, S.; Vandewal, K.; Fei, Z. P.; Heeney, M.; Salleo, A. Macromolecules 2014, 47, 7151.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A composition of matter, comprising:
donor-acceptor copolymers each comprising a main chain section, the main chain section having a repeat unit that comprises a donor and an acceptor, and wherein:
the acceptor comprises a phenylene having the structural formula: 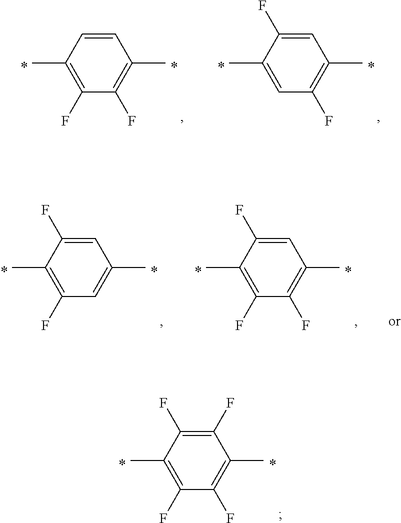
the donor comprises a dithiophene of the structure: 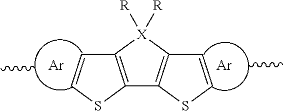
each Ar is independently a substituted or non-substituted aromatic functional group, or each Ar is independently nothing and the valence of its respective thiophene ring is completed with hydrogen,
each R is independently hydrogen or a substituted or non-substituted alkyl, aryl, or alkoxy chain, and
X is C, Si, Ge, N or P.

2. The composition of matter of claim 1, wherein the donor-acceptor copolymers are aligned.

3. The composition of matter of claim 1, wherein the donor-acceptor copolymers are cast from a solution such that the donor-acceptor copolymers have a mobility in a saturation regime of at least 2 cm²V⁻¹s⁻¹.

4. The composition of matter of claim 3, further comprising an organic field effect transistor (OFET) including the donor-acceptor copolymers, wherein the OFET has an on/off ratio of at least 10⁵ or the mobility of at least 2 cm²V⁻¹s⁻¹ and the on/off ratio of at least 10⁵.

5. The composition of matter of claim 1, wherein the donor-acceptor copolymers are cast from a solution such that the donor-acceptor copolymers have a mobility in a saturation regime of at least 0.68 cm²V⁻¹s⁻¹.

6. The composition of matter of claim 5, further comprising an organic field effect transistor (OFET) including the donor-acceptor copolymers, wherein the OFET has an on/off ratio of at least 10⁴, or the mobility of at least 0.68 cm²V⁻¹s⁻¹ and the on/off ratio of at least 10⁴.

7. The composition of matter of claim 1, wherein the donor-acceptor copolymers exhibit unipolar p-type transport characteristics.

8. The composition of matter of claim 1, wherein the donor-acceptor copolymers are regioregular and stacked to form a crystalline structure.

9. The composition of matter of claim 8, wherein the crystalline structure is characterized by one or more peaks having a full width at half maximum of less than 0.1 Angstroms⁻¹ as measured by an out of plane grazing incidence wide angle X-ray Scattering (GIWAXS) measurement of the crystalline structure.

10. The composition of matter of claim 1, wherein the donor-acceptor copolymers have a bandgap of at least 1.9 eV.

11. The composition of matter of claim 1, wherein the donor-acceptor copolymers have a bandgap in a range of 1.9 eV-2.1 eV.

12. The composition of matter of claim 11, wherein the donor-acceptor copolymers have a Lowest Unoccupied Molecular Orbital (LUMO) having an energy greater than −3.5 electron volts.

13. The composition of matter of claim 1, further comprising a film on a substrate, the film comprising the donor-acceptor copolymers, and the film having a surface roughness of less than 2 nanometers over a 5 micron by 5 micron area.

14. An Organic Field Effect Transistor (OFET) including the donor-acceptor copolymers of claim 1, further comprising:
a source contact and a drain contact on the donor-acceptor copolymers;
a gate contact; and
a dielectric between the donor-acceptor copolymers and the gate contact;

15. A method of fabricating a composition of matter, comprising:
fabricating donor-acceptor copolymers each comprising a main chain section, the main chain section having a repeat unit that comprises a donor and an acceptor, wherein:
the acceptor comprises a phenylene having the structural formula: 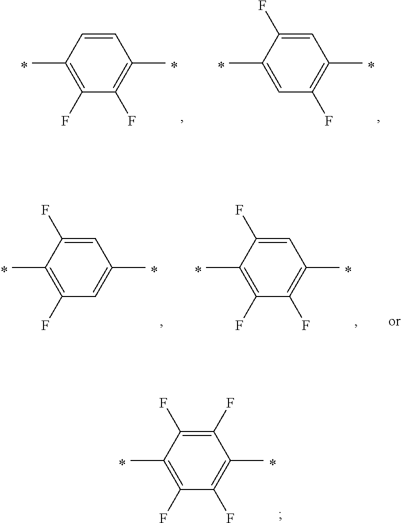
and
the donor comprises a dithiophene of the structure: 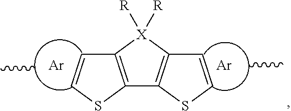
each Ar is independently a substituted or non-substituted aromatic functional group, or each Ar is independently nothing and the valence of its respective thiophene ring is completed with hydrogen,
each R is independently hydrogen or a substituted or non-substituted alkyl, aryl, or alkoxy chain, and
X is C, Si, Ge, N or P.

16. The method of claim 15, further comprising:
reacting one or more first monomers, each comprising the dithiophene and an organostannane, with one or more second monomers each comprising benzene substituted with iodide, bromine, and fluorine, under conditions to form one or more intermediary compounds; and
reacting the first monomers with the intermediary compounds to form the donor-acceptor copolymers.

17. The method of claim 15, further comprising:
reacting one or more first monomers, each comprising a dithiophene and an organostannane, with one or more fluorinated and brominated monomers, under conditions to form the donor-acceptor copolymers.

18. The method of claim 15, wherein donor-acceptor copolymers comprise regioregular donor-acceptor copolymers, the method further comprising heating the regioregular donor-acceptor copolymers so as to maintain or increase a mobility of the donor-acceptor copolymers.

19. A composition of matter, comprising:
a regioregular donor-acceptor copolymer comprising a main chain section, the main chain section having a repeat unit that comprises a donor and an acceptor, and wherein the acceptor comprises a phenylene having the structural formula:

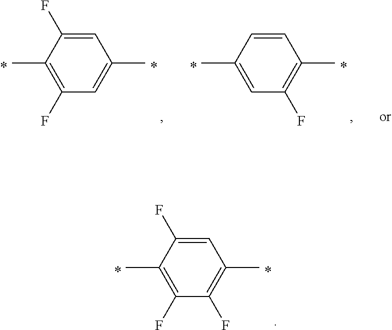

20. The composition of matter of claim 19, wherein:
the donor comprises a dithiophene of the structure: 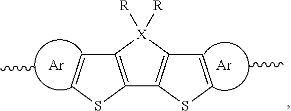
and
each Ar is independently a substituted or non-substituted aromatic functional group, or each Ar is independently nothing and the valence of its respective thiophene ring is completed with hydrogen,
each R is independently hydrogen or a substituted or non-substituted alkyl, aryl, or alkoxy chain, and
X is C, Si, Ge, N or P.
